(19) United States
(12) Patent Application Publication
(10) Pub. No.: US 2024/0188399 A1
(43) Pub. Date: Jun. 6, 2024

(54) DISPLAY APPARATUS AND METHOD OF PROVIDING THE SAME

(71) Applicant: Samsung Display Co., Ltd., Yongin-si (KR)

(72) Inventors: Wooyong Sung, Yongin-si (KR); Taewook Kang, Yongin-si (KR); Woongsik Kim, Yongin-si (KR); Jeongseok Lee, Yongin-si (KR)

(21) Appl. No.: 18/469,156

(22) Filed: Sep. 18, 2023

(30) Foreign Application Priority Data
Dec. 6, 2022 (KR) 10-2022-0169102

(51) Int. Cl. H10K 59/80; H10K 59/12; H10K 59/122

(52) U.S. Cl. CPC H10K 59/879; H10K 59/1201; H10K 59/122; H10K 59/873; G09G 3/3233; G09G 2300/0852

(57) ABSTRACT

A display apparatus includes a light-emitting element including a pixel electrode, an intermediate layer and an opposite electrode, a bank layer including an inorganic bank layer, a first metal bank layer and a second metal bank layer sequentially on the pixel electrode, and the inorganic bank layer, the first metal bank layer, and the second metal bank layer together defining a pixel opening of the bank layer which corresponds to the pixel electrode, an inorganic encapsulation layer on the pixel electrode and having a first refractive index, and a planarization layer on the inorganic encapsulation layer and having a second refractive index which is greater than the first refractive index.

This application claims priority to Korean Patent Application No. 10-2022-0169102, filed on Dec. 6, 2022, and all the benefits accruing therefrom under 35 U.S.C. § 119, the disclosure of which is incorporated by reference herein in its entirety.

### BACKGROUND

### 1. Field

One or more embodiments relate to display apparatuses and methods of manufacturing (or providing) the same.

### 2. Description of the Related Art

Applications of display apparatuses have continuously diversified. Moreover, since display apparatuses have become thinner and lighter, their range of use has expanded.

Display apparatuses include a plurality of pixels that receive electrical signals and emit light to display an image to the outside of the display apparatuses. A pixel of an organic light-emitting display device includes an organic light-emitting diode (OLED) as a display element. The OLED includes a pixel electrode, an emission layer, and an opposite electrode.

### SUMMARY

However, such a conventional display apparatus has a problem in that light emitted in an oblique direction on the upper surface of a substrate is reflected by the upper surface of a cover window, leading to a reduction of light-emission efficiency. One or more embodiments include a display apparatus having improved light-emission efficiency, and a method of manufacturing (or providing) the display apparatus. However, aspects of embodiments are not limited thereto, and the above characteristics do not limit the scope of embodiments according to the disclosure.

Additional aspects will be set forth in portion in the description which follows and, in part, will be apparent from the description, or may be learned by practice of the presented embodiments of the disclosure.

According to one or more embodiments, a display apparatus includes a pixel electrode, a bank layer including an inorganic bank layer, a first metal bank layer, and a second metal bank layer sequentially stacked on one another, the bank layer defining a pixel opening that overlaps the pixel electrode and passes through the inorganic bank layer, the first metal bank layer, and the second metal bank layer, an intermediate layer disposed on the pixel electrode through the pixel opening of the bank layer, an opposite electrode disposed on the intermediate layer through the pixel opening of the bank layer, an inorganic encapsulation layer positioned on the opposite electrode and having a first refractive index, and a planarization layer positioned on the inorganic encapsulation layer and having a second refractive index that is greater than the first refractive index.

The first refractive index of the inorganic encapsulation layer may be about 1.3 to about 1.6, and the second refractive index of the planarization layer may be about 1.6 to about 2.5.

The second metal bank layer may have a tip protruding from a lateral surface of the first metal bank layer that defines the pixel opening.

The inorganic encapsulation layer may be in direct contact with a lower surface of the tip of the second metal bank layer.

The planarization layer may fill at least a portion of the pixel opening.

The display apparatus may further include an organic bank layer positioned between the second metal bank layer and the inorganic encapsulation layer.

The opposite electrode may be in direct contact with a lateral surface of the first metal bank layer that defines the pixel opening.

The display apparatus may further include a protective layer positioned on the planarization layer and having a third refractive index that is less than the second refractive index.

The display apparatus may further include a light-shielding layer positioned on the protective layer and defining a filter opening overlapping the pixel electrode, and a color filter layer corresponding to the pixel electrode.

The planarization layer may be positioned to correspond to the pixel electrode, and, on the bank layer, the inorganic encapsulation layer and the protective layer may be in direct contact with each other.

According to one or more embodiments, a method of manufacturing (or providing) a display apparatus includes forming (or providing) a pixel electrode and an electrode protection layer corresponding to the pixel electrode, forming, on the electrode protection layer, a bank layer including an inorganic bank layer, a first metal bank layer, and a second metal bank layer, forming an organic bank layer defining an opening overlapping the pixel electrode on the bank layer, forming a pixel opening overlapping the pixel electrode and passing through the bank layer, by using the organic bank layer as a mask, forming an intermediate layer disposed on the pixel electrode through the pixel opening of the bank layer, forming an opposite electrode positioned on the pixel electrode through the pixel opening of the bank layer, forming an inorganic encapsulation layer covering the opposite electrode and having a first refractive index, and forming a planarization layer positioned on the inorganic encapsulation layer and having a second refractive index that is greater than the first refractive index.

The forming of the pixel opening may include selectively etching the first metal bank layer among the first metal bank layer and the second metal bank layer, and the second metal bank layer may have a tip protruding from a lateral surface of the first metal bank layer that defines the pixel opening.

The forming of the inorganic encapsulation layer may include depositing the inorganic encapsulation layer so that the inorganic encapsulation layer directly contacts a lower surface of the tip of the second metal bank layer.

The forming of the planarization layer may include forming the planarization layer to fill at least a portion of the pixel opening.

The method may further include forming a protective layer positioned on the planarization layer and having a third refractive index that is less than the second refractive index.

The method may further include, between the forming of the pixel opening and the forming of the intermediate layer, removing the organic bank layer.

The method may further include forming a light-shielding layer positioned on the protective layer and defining a filter opening overlapping the pixel electrode, and forming a color filter layer corresponding to the pixel electrode.

The forming of the intermediate layer may include depositing a material for forming the intermediate layer on the pixel electrode and the bank layer.

The forming of the opposite electrode may include forming the opposite electrode so that the opposite electrode is in direct contact with a lateral surface of the first metal bank layer defining the pixel opening.

The forming of the pixel opening may include removing the electrode protective layer, and a portion of the electrode protective layer may remain on the inorganic bank layer and an edge of the pixel electrode.

These and/or other aspects will become apparent and more readily appreciated from the following description of the embodiments, taken in conjunction with the accompanying drawings.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic perspective view of a display apparatus according to an embodiment;

FIGS. 2 and 3 are schematic cross-sectional views of a display apparatus according to an embodiment;

FIG. 4 is a schematic plan view of a display panel included in a display apparatus according to an embodiment;

FIGS. 5A and 5B are schematic equivalent circuit diagrams of a pixel included in a display apparatus according to an embodiment;

FIG. 6 is a schematic plan view of an input sensing layer included in a display apparatus according to an embodiment;

FIGS. 7A through 7H are schematic cross-sectional views of operations of a method of manufacturing (or providing) a display apparatus, according to an embodiment;

FIG. 7I is a cross-sectional view of a stacking structure of a light-emitting diode according to an embodiment; and

FIGS. 8A through 8K are schematic cross-sectional views of some operations of a method of manufacturing a display apparatus, according to an embodiment.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the present disclosure are shown. The disclosure may, however, be embodied in many different forms and should not be construed as limited to the embodiments set forth herein.

One or more embodiments will be described below in more detail with reference to the accompanying drawings. Those components that are the same as or are in correspondence with each other are rendered the same reference numeral regardless of the figure number, and redundant explanations are omitted. Within the Figures and the text of the disclosure, a reference number indicating a singular form of an element may also be used to reference a plurality of the singular element.

It will be understood that although the terms “first,” “second,” etc. may be used herein to describe various components, these components should not be limited by these terms. These components are only used to distinguish one component from another.

The terminology used herein is for the purpose of describing particular embodiments only and is not intended to be limiting. As used herein, the singular forms “a,” “an,” and “the” are intended to include the plural forms as well, unless the context clearly indicates otherwise.

The terms “comprises” and/or “comprising” used herein specify the presence of stated features or components, but do not preclude the presence or addition of one or more other features or components.

When a layer, region, or component is referred to as being related to another element such as being “on” or “formed on” another layer, region, or component, it can be directly or indirectly formed on the other layer, region, or component. That is, for example, intervening layers, regions, or components may be present. In contrast, when a layer, region, or component is referred to as being related to another element such as being “directly on” or “formed directly on” another layer, region, or component, no intervening layer, region or component is present.

When a layer, region, or component is referred to as being “connected” or “coupled” to another layer, region, or component, it can be directly connected or coupled to the other layer, region, or/and component or intervening layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present.

In the present specification, “A and/or B” represents A or B, or A and B. The expression “at least one of A and B” indicates only A, only B, both A and B, or variations thereof. For example, “an element” has the same meaning as “at least one element,” unless the context clearly indicates otherwise. “At least one” is not to be construed as limiting “a” or “an.” “Or” means “and/or.”

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terms “about” or “approximately” used herein to refer to any numerical value may refer to inclusion of numerical values within a range generally accepted in the technical field due to measurement limitations or errors. For example, “about” may refer to inclusion of values in the range of ±30%, ±20%, ±10%, or ±5% of any numerical value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

When an embodiment may be implemented differently, a specific process order may be performed differently from the described order. For example, two consecutively described processes may be performed substantially at the same time or performed in an order opposite to the described order.

Sizes of elements in the drawings may be exaggerated or reduced for convenience of explanation. For example, since sizes and thicknesses of components in the drawings are arbitrarily illustrated for convenience of explanation, embodiments are not limited thereto.

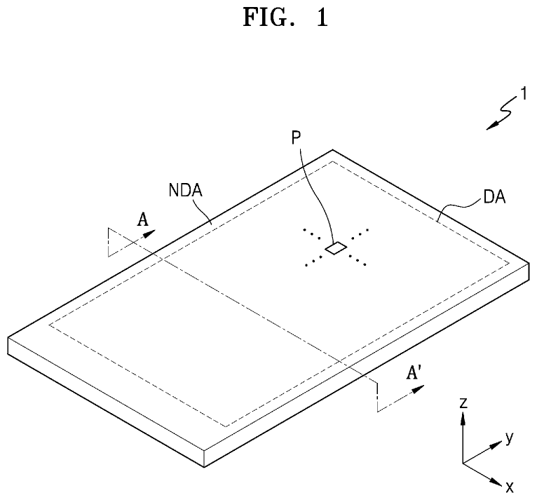

FIG. 1 is a schematic perspective view of a display apparatus 1 according to an embodiment.

Referring to FIG. 1, the display apparatus 1 may include a display area DA and a non-display area NDA which is adjacent to the display area DA, such as being around the display area DA. The display area DA may display an image through one or more pixel P among a plurality of pixels P arranged in the display area DA. The non-display area NDA is located outside the display area DA (e.g., closer to an outer edge of the display apparatus 1) and does not display an image. In an embodiment, the non-display area NDA may extend along all sides of the display area DA to surround an entirety of the display area DA.

A driver or the like for providing an electrical signal or power to the display area DA may be disposed in the non-display area NDA. A terminal in an area where an electronic device or a printed circuit board (PCB) 30 may be electrically connected, may be disposed in the non-display area NDA. That is, component like the PCB 30 may be connected to the display apparatus 1 at a first terminal area 14 including the terminal.

As an embodiment, FIG. 1 illustrates that the display area DA is a polygon (e.g., a quadrangle) of which a length in an x direction is less than that in a y direction. However, the disclosure is not limited thereto. As another embodiment, the display area DA may have various shapes such as an N-gon (where ‘N’ is a natural number equal to or greater than 3), a circle, or an ellipse. The display area DA may include a side at a boundary between the display area DA and the non-display area NDA. In FIG. 1, for example, each of the corners of the display area DA includes a vertex where straight lines or boundary sides meet each other. However, in another embodiment, the display area DA may be a polygon with rounded corners.

The display apparatus 1 and various components or layers thereof may have a thickness defined along the z direction as a thickness direction. The display apparatus 1 and various components or layers thereof may include a display area DA and a non-display area NDA respectively corresponding to those described above.

A case in which the display apparatus 1 is an electronic device that is a smartphone will now be described for convenience of description, but the display apparatus 1 of the disclosure is not limited thereto. The display apparatus 1 is applicable to not only portable electronic apparatuses, such as mobile phones, smartphones, tablet personal computers (PCs), mobile communication terminals, electronic notebooks, electronic books, portable multimedia players (PMPs), navigation devices, and ultra mobile PCs (UMPCs) but also various products, such as televisions, notebooks, monitors, advertisement panels, and Internet of things (IoT) devices. The display apparatus 1 according to an embodiment is also applicable to wearable devices, such as smart watches, watch phones, glasses-type displays, and head mounted displays (HMDs). The display apparatus 1 according to an embodiment is also applicable to dashboards of automobiles, center information displays (CIDs) of the center fasciae or dashboards of automobiles, room mirror displays that replace the side mirrors of automobiles, and displays arranged on the rear sides of front seats to serve as entertainment devices for back seat passengers of automobiles.

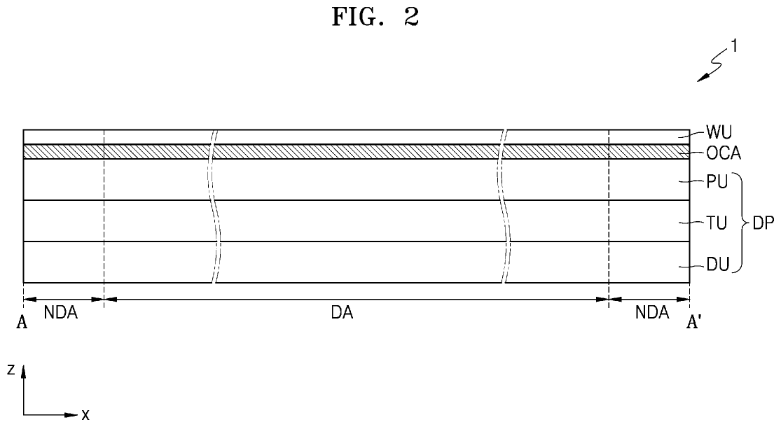

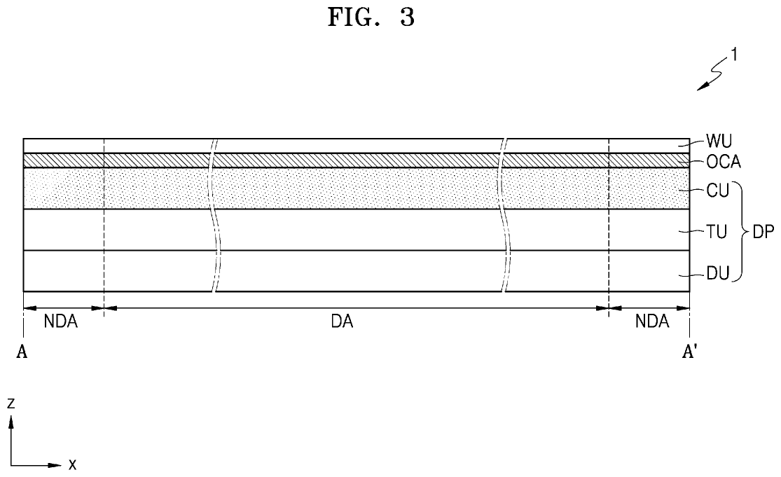

FIGS. 2 and 3 are schematic cross-sectional views of a display apparatus 1 according to an embodiment. FIGS. 2 and 3, which are cross-sectional views schematically illustrating a cross-section taken along line A-A′ of the display apparatus 1 of FIG. 1, and are used to explain a stacking relationship between functional panels and/or functional layers that together constitute the display apparatus 1. While FIGS. 2 and 3 show structures arranged along the x direction, it will be understood that such structures may also be arranged along the y direction.

Referring to FIG. 2, the display apparatus 1 according to an embodiment may include a display layer DU, an input sensing layer TU, an anti-reflection layer PU, and a window layer WU. At least some components from among the display layer DU, the input sensing layer TU, the anti-reflection layer PU, and the window layer WU may be formed by consecutive processes or may be combined with each other via a separate layer such as an adhesion member. FIG. 2 illustrates an optically clear adhesion member OCA as the adhesion member. According to an embodiment, the anti-reflection layer PU and the window layer WU may be replaced by other components or may be omitted.

According to an embodiment, the input sensing layer TU is arranged directly on the display layer DU. In the present specification, the sentence “A component B is arranged directly on a component A” means that there are no adhesion layers/adhesion members arranged between the components A and B. In an embodiment, the component B is formed (or provided) on a base surface of the component A via a consecutive process after the component A is formed. In an embodiment, layers or components which are related “directly” may form an interface therebetween, such as physically and/or mechanically contacting each other.

The display layer DU, the input sensing layer TU arranged directly on the display layer DU, and the anti-reflection layer PU may together be defined as a display panel DP.

The display layer DU generates an image, and the input sensing layer TU obtains coordinate information of an external input (for example, a touch event). The display layer DU may include a plurality of display elements and/or a plurality of light-emitting elements to defined a display element layer. Although not illustrated separately, the display panel DP according to an embodiment may further include a protection member arranged on a lower surface of the display layer DU, where the lower surface is a surface furthest from the window (e.g., the window layer WU). The protection member and the display layer DU may be combined with each other via an adhesion member.

The input sensing layer TU may have a multi-layered structure. The input sensing layer TU includes a detection electrode, a signal line (or trace line) connected to the detection electrode, and at least one insulating layer. The input sensing layer TU may sense an external input according to, for example, in an electrostatic capacitive method. An operation method of the input sensing layer TU is not particularly limited in the disclosure. According to an embodiment, the input sensing layer TU may sense an external input according to an electromagnetic induction method or a pressure detection method.

The anti-reflection layer PU reduces reflectivity of external light that is incident thereon in a direction from the top of the window layer WU, where the top of the window layer WU may be furthest from the display panel DP. The anti-reflection layer PU according to an embodiment may include a phase retarder and a polarizer. The phase retarder may be of a film type or liquid coating type, and may include a λ/2 phase retarder and/or a λ/4 phase retarder. The polarizer may also be of a film type or liquid coating type. The film type polarizer may include a stretchable synthetic resin film, and the liquid coating type polarizer may include liquid crystals arranged in a certain arrangement. The phase retarder and the polarizer may further include protective films, respectively. The phase retarder and the polarizer, or the protective films may be defined as a base layer of the anti-reflection layer PU.

According to an embodiment, as shown in FIG. 2, the optically clear adhesion member OCA may be disposed between the anti-reflection layer PU and the window layer WU and couple the anti-reflection layer PU to the window layer WU. According to another embodiment, the anti-reflection layer PU may not be directly disposed on the input sensing layer TU, and the optically transparent adhesive member OCA may be disposed between the anti-reflection layer PU and the input sensing layer TU. The window layer WU may include a glass material.

Referring to FIG. 3, the display panel DP may include the display layer DU, the input sensing layer TU, and a color filter layer CU. The color filter layer CU may be disposed directly on the input sensing layer TU.

The color filter layer CU may include a color filter included to correspond to a light-emission region of each pixel P, and a light shielding layer included to correspond to a non-light-emission region which is between pixels P. According to an embodiment, no optically clear adhesion members OCA may be between the color filter layer CU and the display panel DP, and the color filter layer CU may be directly on the display panel DP. The optically clear adhesion member OCA may be disposed between the color filter layer CU and the window layer WU.

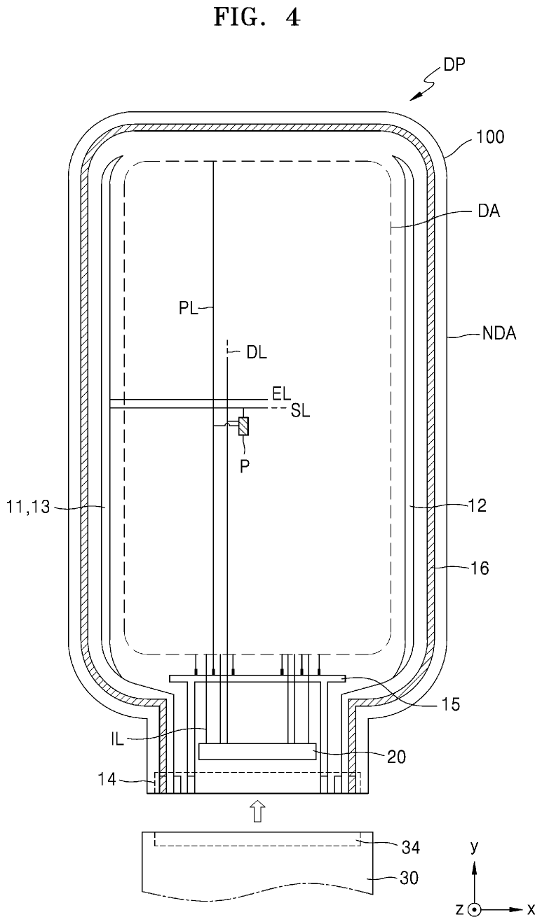

FIG. 4 is a schematic plan view of a display panel DP included in a display apparatus 1 according to an embodiment.

Referring to FIG. 4, the display panel DP includes a display area DA, and a non-display area NDA which is outside the display area DA. The display area DA is an area (e.g., a planar area) for displaying an image, and a plurality of pixels P may be arranged in the display area DA. Although FIG. 4 illustrates that the display area DA has a shape of a rectangle having approximately rounded corners, the disclosure is not limited thereto. As described above, the display area DA may have various shapes such as an N-gon (where ‘N’ is a natural number equal to or greater than 3), a circle, or an ellipse.

Each of the plurality of pixels P may otherwise refer to a subpixel and may include a display element such as an organic light-emitting diode (OLED) which generates light, emits light, displays an image, etc. The pixel P may emit, for example, red light, green light, blue light, or white light.

The non-display area NDA may be disposed outside the display area DA. Outer circuits for driving the pixels P may be arranged in the non-display area NDA and be connected to the pixels P. For example, a first scan driving circuit 11, a second scan driving circuit 12, an emission control driving circuit 13, a first terminal area 14, a driving power supply line 15, and a common power supply line 16 may be arranged in the non-display area NDA.

The first scan driving circuit 11 may provide a scan signal to the pixel P via a scan line SL. The second scan driving circuit 12 may be disposed side by side with the first scan driving circuit 11 with the display area DA therebetween. Some of the plurality of pixels P arranged in the display area DA may be electrically connected to the first scan driving circuit 11, and remaining ones of the plurality of pixels P may be connected to the second scan driving circuit 12. In an embodiment, the second scan driving circuit 12 may be omitted, and all of the pixels P disposed in the display area DA may be electrically connected to the first scan driving circuit 11.

The emission control driving circuit 13 may be disposed on the same side of the display area DA as the first scan driving circuit 11 and may provide an emission control signal to the pixel P via an emission control line EL. Although the emission control driving circuit 13 is disposed on only one side of the display area DA in FIG. 1, the emission control driving circuit 13 may be disposed on both sides of the display area DA, similar to the first scan driving circuit 11 and the second scan driving circuit 12.

A driving chip 20 may be disposed in the non-display area NDA. The driving chip 20 may include an integrated circuit for driving the display panel DP. The integrated circuit may be a data driving integrated circuit for generating a data signal, however, the disclosure is not limited thereto.

The first terminal area 14 may be disposed in the non-display area NDA. The first terminal area 14 may be exposed to outside the display panel DP without being covered such as by an insulating layer. A terminal in the first terminal area 14 which is exposed may be electrically connected to a printed circuit board (PCB) 30. A second terminal area 34 of the PCB 30 may be electrically connected to the first terminal area 14 of the display panel DP.

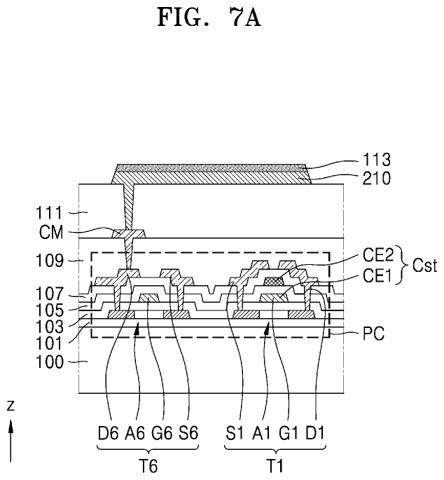

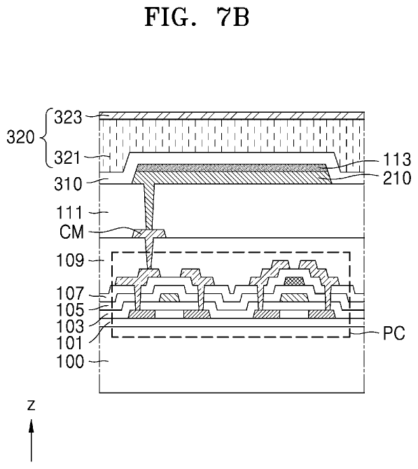

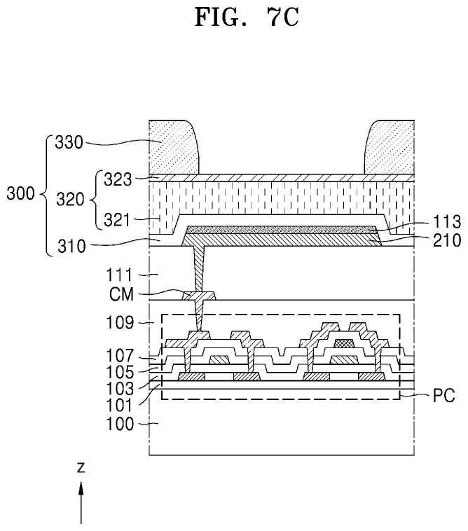

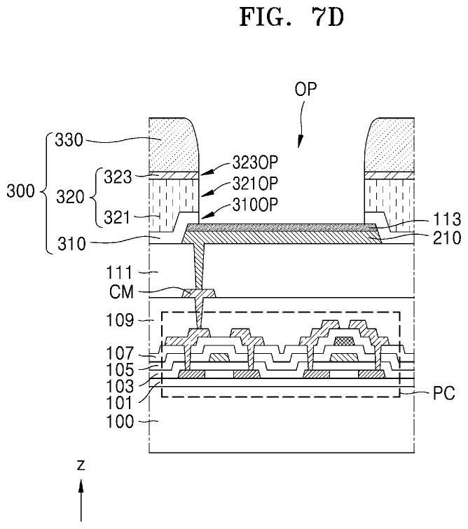

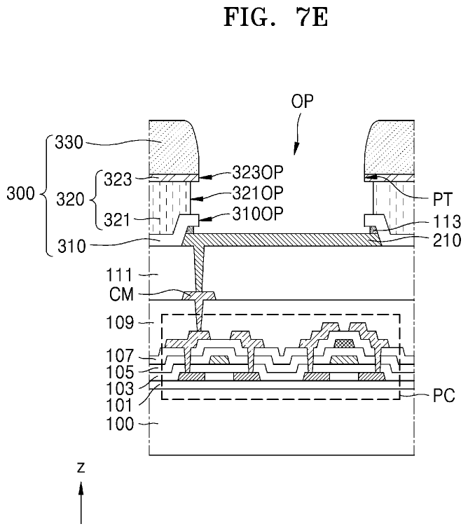

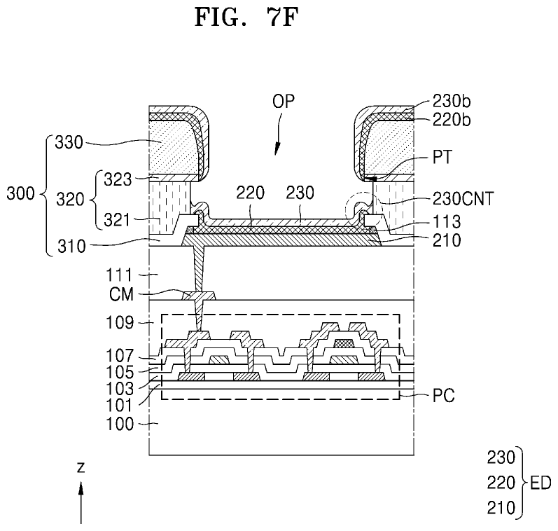

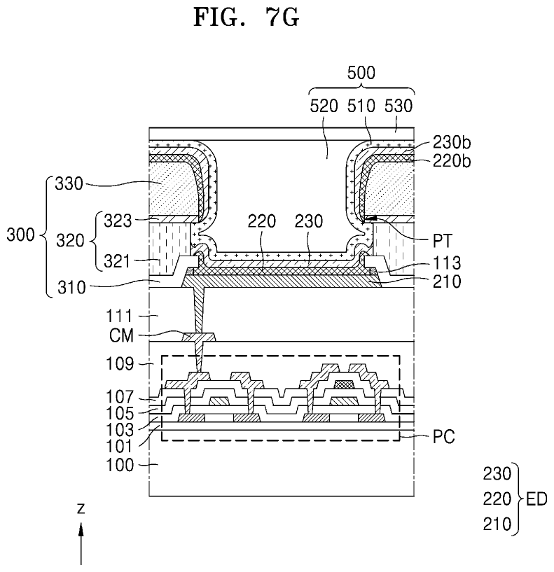

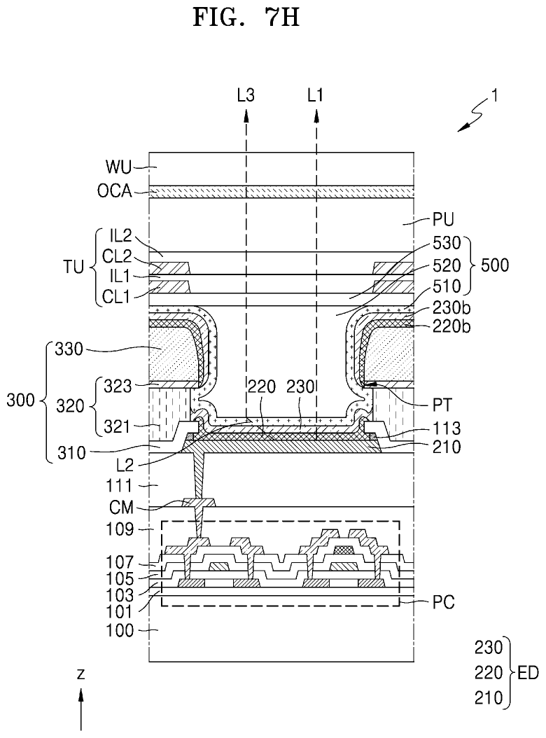

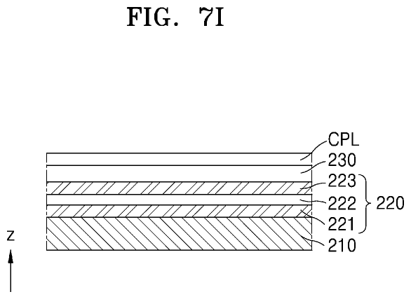

The PCB 30 transmits a signal or power of a controller (not shown) to the display panel DP. A control signal generated by the controller may be transmitted to each of driving circuits via the PCB 30. The controller may transmit a driving voltage ELVDD to the driving power supply line 15 and provide a common voltage ELVSS to the common power supply line 16. The driving voltage ELVDD may be transmitted to each of the plurality of pixels P via a driving voltage line PL connected to the driving power supply line 15, and the common voltage ELVSS may be transmitted to an opposite electrode 230 of each of the plurality of pixels P via a metal bank layer 320 (see FIG. 7H) connected to the common power supply line 16. The driving power supply line 15 may have a shape extending in one direction (e.g., the x direction) from the lower side of the display area DA. The common power supply line 16 may partially surround the display area DA by having a loop shape of which one side is open.

The controller may generate a data signal, and the generated data signal may be transmitted to an input line IL via the driving chip 20 and may be transmitted to a data line DL connected to the input line IL. For reference, the term ‘line’ may refer to a ‘wiring’ such as a signal wiring, an electrical wiring, a conductive wiring, etc. This is equally applied to embodiments to be described later and modifications thereof.

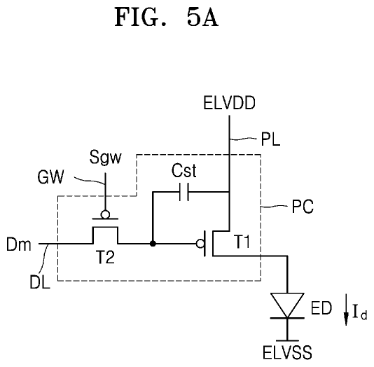

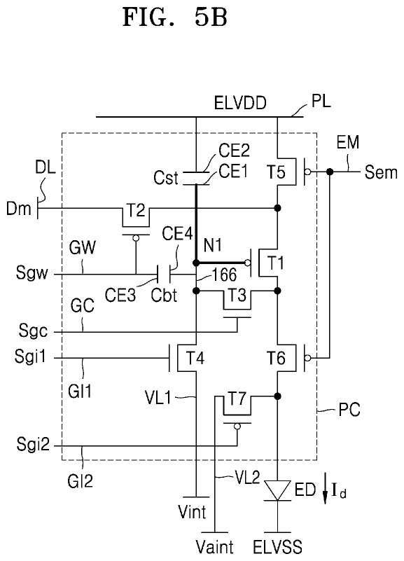

FIGS. 5A and 5B are schematic equivalent circuit diagrams of a pixel P included in a display apparatus 1 according to an embodiment.

Referring to FIG. 5A, a light-emitting diode ED as a non-limiting example of a light-emitting element may be electrically connected to a pixel circuit PC, and the pixel circuit PC may include a first transistor T1, a second transistor T2, and a storage capacitor Cst. The pixel circuit PC may be included in a circuit layer. That is, the display layer DU as a display element layer (or a light-emitting element layer) is connected to the circuit layer.

The second transistor T2 transmits, to the first transistor T1, a data signal Dm received via the data line DL according to a scan signal Sgw received via a scan line GW.

The storage capacitor Cst is connected to the second transistor T2 and the driving voltage line PL, and stores a voltage corresponding to a difference between a voltage received from the second transistor T2 and the driving voltage ELVDD supplied to the driving voltage line PL.

The first transistor T1 may be connected to the driving voltage line PL and the storage capacitor Cst, and may control a driving current I_{d} flowing from the driving voltage line PL to the light-emitting diode ED, in accordance with a voltage value stored in the storage capacitor Cst. An opposite electrode 230 (for example, a cathode) of the light-emitting diode ED may receive the common voltage ELVSS. The light-emitting diode ED may emit light having a certain brightness by the driving current I_{d}.

Although a case where the pixel circuit PC includes two transistors and one storage capacitor is illustrated in FIG. 5A, the disclosure is not limited thereto.

Referring to FIG. 5B, the pixel circuit PC may include seven transistors and two capacitors.

The pixel circuit PC may include first, second, third, fourth, fifth, sixth, and seventh transistors T1, T2, T3, T4, T5, T6, and T7, a storage capacitor Cst, and a boost capacitor Cbt. According to another embodiment, the pixel circuit PC may not include the boost capacitor Cbt.

Some of the first, second, third, fourth, fifth, sixth, and seventh transistors T1, T2, T3, T4, T5, T6, and T7 may be n-channel metal oxide semiconductor (NMOS) transistors, e.g., NMOS field effect transistors (N-MOSFETs), and the others may be p-channel metal oxide semiconductor (PMOS) transistors, e.g., PMOS field effect transistors (P-MOSFETs). According to another embodiment, the third, fourth, and seventh transistors T3, T4, and T7 may be n-channel metal oxide semiconductor (NMOS) transistors, e.g., NMOS field effect transistors (N-MOSFETs), and the others may be p-channel metal oxide semiconductor (PMOS) transistors, e.g., PMOS field effect transistors (P-MOSFETs).

The first, second, third, fourth, fifth, sixth, and seventh transistors T1, T2, T3, T4, T5, T6, and T7, the storage capacitor Cst, and the boost capacitor Cbt may be connected to signal lines. The signal lines may include a scan line GW, an emission control line EM, a compensation gate line GC, a first initialization gate line GI1, a second initialization gate line GI2, and a data line DL. The pixel circuit PC may be electrically connected to voltage lines, for example, a driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to a pixel electrode (e.g., an anode) of the light-emitting diode ED via the sixth transistor T6. One of the first electrode and the second electrode of the first transistor T1 may be a source electrode, and the other may be a drain electrode. The first transistor T1 may supply the driving current Id to the light-emitting diode ED according to a switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be connected to the first electrode of the first transistor T1 and electrically connected to the driving voltage line PL via the fifth transistor T5. One of the first electrode and the second electrode of the second transistor T2 may be a source electrode, and the other may be a drain electrode. The second transistor T2 may be turned on according to the scan signal Sgw received via the scan line GW and may perform a switching operation of transmitting the data signal Dm received through the data line DL to the first electrode of the first transistor T1.

The third transistor T3 may be a compensating transistor that compensates for a threshold voltage of the first transistor T1. A third gate electrode of the third transistor T3 is connected to the compensation gate line GC. A first electrode of the third transistor T3 is connected to a lower electrode CE1 of the storage capacitor Cst and the first gate electrode of the first transistor T1 through a node connection line 166. A first electrode of the third transistor T3 may be connected to the fourth transistor T4. A second electrode of the third transistor T3 is electrically connected to the pixel electrode (e.g., an anode) of the light-emitting diode ED via the sixth transistor T6 while being connected to the second electrode of the first transistor T1. One of the first electrode and the second electrode of the third transistor T3 may be a source electrode, and the other may be a drain electrode.

The third transistor T3 is turned on according to a compensation signal Sgc received via the compensation gate line GC and electrically connects the first gate electrode and the second electrode (e.g., a drain electrode) of the first transistor T1 to each other, such that the first transistor T1 is diode-connected.

The fourth transistor T4 may be a first initializing transistor that initializes the first gate electrode of the first transistor T1. A fourth gate electrode of the fourth transistor T4 is connected to the first initialization gate line GI1. A first electrode of the fourth transistor T4 is connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and the other may be a drain electrode. The fourth transistor T4 may be turned on in response to a first initialization signal Sgi1 received through the first initialization gate line GI1, to perform an initialization operation of initializing the voltage of the first gate electrode of the first transistor T1 by transmitting a first initializing voltage Vint to the first gate electrode of the first transistor T1.

The fifth transistor T5 may be an operation control transistor. A fifth gate electrode of the fifth transistor T5 is connected to the emission control line EM, a first electrode of the fifth transistor T5 is connected to the driving voltage line PL, and a second electrode of the fifth transistor T5 is connected to the first electrode of the first transistor T1 and the second electrode of the second transistor T2. One of the first electrode and the second electrode of the fifth transistor T5 may be a source electrode, and the other may be a drain electrode.

The sixth transistor T6 may be an emission control transistor. A sixth gate electrode of the sixth transistor T6 is connected to the emission control line EM, a first electrode of the sixth transistor T6 is connected to the second electrode of the first transistor T1 and the second electrode of the third transistor T3, and a second electrode of the sixth transistor T6 is electrically connected to a second electrode of the seventh transistor T7 and the pixel electrode (e.g., an anode) of the light-emitting diode ED. One of the first electrode and the second electrode of the sixth transistor T6 may be a source electrode, and the other may be a drain electrode.

The fifth transistor T5 and the sixth transistor T6 may be simultaneously turned on according to an emission control signal Sem received via the emission control line EM, and thus the driving voltage ELVDD may be transmitted to the light-emitting diode ED such that the driving current I_{d} may flow in the light-emitting diode ED.

The seventh transistor T7 may be a second initializing transistor that initializes the pixel electrode (e.g., an anode) of the light-emitting diode ED. A seventh gate electrode of the seventh transistor T7 is connected to the second initialization gate line GI2. A first electrode of the seventh transistor T7 is connected to the second initialization voltage line VL2. The second electrode of the seventh transistor T7 is connected to the second electrode of the sixth transistor T6 and the pixel electrode (e.g., an anode) of the light-emitting diode ED. The seventh transistor T7 may be turned on in response to a second initialization signal Sgi2 received through the second initialization gate line GI2, to initialize the pixel electrode (e.g., an anode) of the light-emitting diode ED by transmitting a second initializing voltage Vaint to the pixel electrode of the light-emitting diode ED.

According to some embodiments, the second initialization gate line GI2 may be a next scan line. For example, a second initialization gate line GI2 connected to a seventh transistor T7 of a pixel circuit PC disposed in an i-th row (where ‘i’ is a natural number) may correspond to a scan line of a pixel circuit PC disposed in an (i+1)-th row. According to another embodiment, the second initialization gate line GI2 may be an emission control line EM. For example, the emission control line EM may be electrically connected to the fifth, sixth, and seventh transistors T5, T6, and T7.

The storage capacitor Cst includes the lower electrode CE1 and an upper electrode CE2. The lower electrode CE1 of the storage capacitor Cst is connected to the first gate electrode of the driving transistor T1, and the upper electrode CE2 of the storage capacitor Cst is connected to the driving voltage line PL. The storage capacitor Cst may store a charge corresponding to a difference between the voltage of the first gate electrode of the first transistor T1 and the driving voltage ELVDD.

The boost capacitor Cbt includes a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. The boost capacitor Cbt may increase the voltage of a first node N1 when the scan signal Sgw supplied to the scan line GW is turned off, and, when the voltage of the first node N1 increases, black gradation may be clearly expressed.

The first node N1 may be a region to which the first gate electrode of the first transistor T1, the first electrode of the third transistor T3, the second electrode of the fourth transistor T4, and the fourth electrode CE4 of the boost capacitor Cbt are connected to each other.

In one embodiment, FIG. 5B shows that the third and fourth transistors T3 and T4 are n-channel MOSFETs (NMOS), and the first, second, fifth, sixth, and seventh transistors T1, T2, T5, T6, and T7 are p-channel MOSFETs (PMOSs). The first transistor T1 directly affecting the brightness of the display apparatus includes a semiconductor layer including polycrystal silicon having high reliability, and thus a high-resolution display apparatus may be realized.

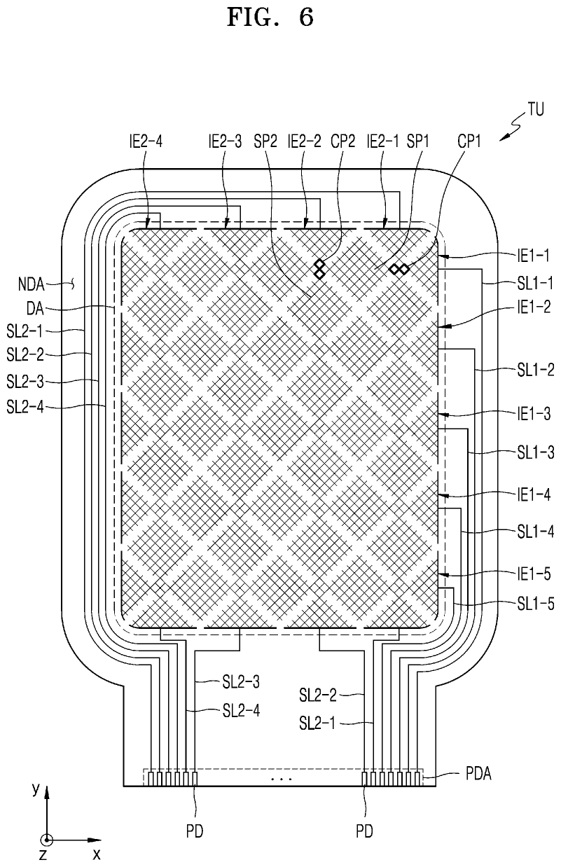

FIG. 6 is a schematic plan view of an input sensing layer TU included in a display apparatus 1 according to an embodiment.

Referring to FIG. 6, the input sensing layer TU may include first detection electrodes IE1-1 through IE1-5, first signal lines SL1-1 through SL1-5 connected to the first detection electrodes IE1-1 through IE1-5, second detection electrodes IE2-1 through IE2-4, and second signal lines SL2-1 through SL2-4 connected to the second detection electrodes IE2-1 through IE2-4.

Although not shown in the drawings, the input sensing layer TU may further include optical dummy electrodes arranged on (or at) boundary areas between the first detection electrodes IE1-1 through IE1-5 and the second detection electrodes IE2-1 through IE2-4.

The first detection electrodes IE1-1 through IE1-5 intersect with the second detection electrodes IE2-1 through IE2-4. The first detection electrodes IE1-1 through IE1-5 may be arranged in (or along) the second direction (e.g., the y direction), and each of the first detection electrodes IE1-1 through IE1-5 may extend in the first direction (e.g., the x direction). The second detection electrodes IE2-1 through IE2-4 may be arranged in the first direction (e.g., the x direction), and each of the second detection electrodes IE2-1 through IE2-4 may extend in the second direction (e.g., the y direction).

Each of the first detection electrodes IE1-1 through IE1-5 includes first sensors SP1 and first connectors CP1 which are arranged along the first direction. Each of the second detection electrodes IE2-1 through IE2-5 include second sensors SP2 and second connectors CP2 which are arranged along the second direction.

Two first sensors SP1 respective at both of opposing ends of a first detection electrode from among the first sensors SP1 may each have a smaller size than a first sensor SP1 on (or at) the center of the first detection electrode, for example, a size that is about half of the size of the first sensor SP1 on the center of the first detection electrode. As used herein, “size” may indicate a planar dimension or a planar area, without being limited thereto. Such planar dimension or planar area may be taken along a plane defined by the first direction and the second direction crossing each other. A view along the third direction of such plane may define a plan view.

Similarly, two second sensors SP2 on both ends of a second detection electrode from among the second sensors SP2 may have a smaller size than a second sensor SP2 on the center of the first detection electrode, for example, a size that is about half of the size of the first sensor SP1 on the center of the first detection electrode.

FIG. 6 illustrates a planar shape of the first detection electrodes IE1-1 through IE1-5 and a planar shape the second detection electrodes IE2-1 through IE2-4 according to an embodiment, but the planar shapes thereof are not limited. According to an embodiment, each of the first detection electrodes IE1-1 through IE1-5 and the second detection electrodes IE2-1 through IE2-4 may have a planar shape (e.g., a bar shape) in which a respective sensor and a respective connector are not distinguished from each other. FIG. 6 illustrates the first sensors SP1 and the second sensors SP2 each having a diamond shape as a planar shape, but the disclosure is not limited thereto. Each of the first sensors SP1 and the second sensors SP2 may have any of other polygonal shapes.

The first sensors SP1 within one first detection electrode among the first detection electrodes IE1-1 through IE1-5 are arranged in the first direction (e.g., the x direction), and the second sensors SP2 within one second detection electrode among the second detection electrodes IE2-1 through IE2-4 are arranged in the second direction (e.g., the y direction). Each of the first connectors CP1 connects adjacent first sensors SP1 to each other, and each of the second connectors CP2 connects adjacent second sensors SP2 to each other.

The first signal lines SL1-1 through SL1-5 are connected to respective one ends (e.g., first ends) of the first detection electrodes IE1-1 through IE1-5, respectively. The second signal lines SL2-1 through SL2-4 are connected to respective both ends of the second detection electrodes IE2-1 through IE2-4, respectively. According to another embodiment, the first signal lines SL1-1 through SL1-5 may be connected to respective both ends of the first detection electrodes IE1-1 through IE1-5, respectively. According to another embodiment, the second signal lines SL2-1 through SL2-4 may be connected to respective one ends of the second detection electrodes IE2-1 through IE2-4, respectively.

The first signal lines SL1-1 through SL1-5 and the second signal lines SL2-1 through SL2-4 may be connected to a pad PD among a plurality of pads PD located at one side of the input sensing layer TU. The pads PD may be arranged in a pad area PDA.

According to an embodiment, locations of the first signal lines SL1-1 through SL1-5 may be interchanged with those of the second signal lines SL2-1 through SL2-4. In contrast with FIG. 6, the first signal lines SL1-1 through SL1-5 may be arranged on the left side, and the second signal lines SL2-1 through SL2-4 may be arranged on the right side.

According to the present embodiment, each of the first detection electrodes IE1-1 through IE1-5 and the second detection electrodes IE2-1 through IE2-4 may have a mesh shape. The mesh shape may be defined at a sensor portion and/or at a connector portion. The mesh shape may be defined by solid portions of a respective detection electrode which are spaced apart from each other and define gaps therebetween. Since each of the first detection electrodes IE1-1 through IE1-5 and the second detection electrodes IE2-1 through IE2-4 has a mesh shape, parasitic capacitance between the first and second detection electrodes IE1-1 through IE1-5 and IE2-1 through IE2-4 and electrodes (for example, an opposite electrode 230) of the display layer DU of FIG. 4 may be reduced. As will be described later, the first detection electrodes IE1-1 through IE1-5 and the second detection electrodes IE2-1 through IE2-4 do not overlap light-emission areas, and thus are not visually recognized from outside the display apparatus 1, such as by a user of the display apparatus 1.

The first detection electrodes IE1-1 through IE1-5 and the second detection electrodes IE2-1 through IE2-4 each having a mesh shape may include metal on which a low-temperature process may be executed to form a low-temperature processed metal. The material of the metal may define the solid portion of the mesh shape and include, for example, silver, aluminum, copper, chromium, nickel, and/or titanium. Accordingly, even when the input sensing layer TU is formed via a consecutive process, damage to a light-emitting diode ED of FIG. 7H may be prevented.

FIGS. 7A through 7H are cross-sectional views schematically illustrating operations of a method of manufacturing (or providing) a display apparatus', according to an embodiment, and FIG. 7I is a cross-sectional view illustrating a stack structure of a light-emitting diode according to an embodiment.

Referring to FIG. 7A, a pixel circuit PC, and a pixel electrode 210 which is electrically connected to the pixel circuit PC may be formed (or providing) on a substrate 100. The substrate 100 may include a glass material or polymer resin. The substrate 100 may have a structure in which a base layer including a polymer resin and an inorganic barrier layer are stacked. The polymer resin may be polyethersulfone (PES), polyacrylate (PAR), polyetherimide (PEI), polyethyelene napthalate (PEN), polyethyelene terephthalate (PET), polyphenylene sulfide (PPS), polyarylate, polyimide (PI), polycarbonate (PC), cellulose triacetate (TAC), cellulose acetate propionate (CAP), or the like.

A buffer layer 101 may be disposed on an upper surface of the substrate 100. The buffer layer 101 may prevent impurities from penetrating into a semiconductor layer of a transistor. The buffer layer 101 may include an inorganic insulating material, such as silicon nitride, silicon oxynitride, or silicon oxide, and may be a single layer or multiple layers including the inorganic insulating material.

The pixel circuit PC may be disposed on the buffer layer 101. The pixel circuit PC may include a plurality of transistors and a storage capacitor as shown in FIG. 5A or 5B. According to an embodiment, FIG. 7A illustrates a first transistor T1, a sixth transistor T6, and a storage capacitor Cst of the pixel circuit PC.

The first transistor T1 may include a first semiconductor layer A1 on the buffer layer 101 and a first gate electrode G1 overlapping a channel region of the first semiconductor layer A1. The first semiconductor layer A1 may include a silicon-based semiconductor material, for example, polysilicon. The first semiconductor layer A1 may include the channel region, and a first region and a second region respectively arranged on both sides of the channel region, that is, at opposing sides of the channel region. The first region and the second region are regions containing higher concentrations of impurities than the channel region, and one of the first region and the second region may correspond to a source region and the other may correspond to a drain region.

The sixth transistor T6 may include a sixth semiconductor layer A6 on the buffer layer 101 and a sixth gate electrode G6 overlapping a channel region of the sixth semiconductor layer A6. The sixth semiconductor layer A6 may include a silicon-based semiconductor material, for example, polysilicon. The sixth semiconductor layer A6 may include the channel region, and a first region and a second region respectively disposed on both sides of the channel region. The first region and the second region are regions containing higher concentrations of impurities than the channel region, and one of the first region and the second region may correspond to a source region and the other may correspond to a drain region.

The first gate electrode G1 and the sixth gate electrode G6 may include a conductive material including molybdenum (Mo), aluminum (Al), copper (Cu), and titanium (Ti), and may each be a multi-layer or single layer including the aforementioned materials. A first gate insulating layer 103 for electrical insulation from the first semiconductor layer A1 and the sixth semiconductor layer A6 may be disposed below the first gate electrode G1 and the sixth gate electrode G6. The first gate insulating layer 103 may include an inorganic insulating material, such as silicon nitride, silicon oxynitride, or silicon oxide, and may be a single layer or multiple layers including the inorganic insulating material.

The storage capacitor Cst may include a lower electrode CE1 and an upper electrode CE2 overlapping each other. According to an embodiment, the lower electrode CE1 of the storage capacitor Cst may include or be the same pattern as the first gate electrode G1. In other words, the first gate electrode G1 may be the lower electrode CE1 of the storage capacitor Cst. For example, the first gate electrode G1 may be integrally formed with the lower electrode CE1 of the storage capacitor Cst. That is, the first gate electrode G1 and the lower electrode CE1 may be respective patterns or portions of a same material layer.

A first interlayer insulating layer 105 may be disposed between the lower electrode CE1 and the upper electrode CE2 of the storage capacitor Cst. The first interlayer insulating layer 105 may include an inorganic insulating material, such as silicon oxide, silicon nitride, or silicon oxynitride, and may be a single layer or multiple layers including the inorganic insulating material.

The upper electrode CE2 of the storage capacitor Cst may include a low-resistance conductive material such as molybdenum (Mo), aluminum (Al), copper (Cu), and/or titanium (Ti), and may have a multi-layer or single layer structure including the aforementioned materials.

A second interlayer insulating layer 107 may be disposed on the storage capacitor Cst. The second interlayer insulating layer 107 may include an inorganic insulating material, such as silicon oxide, silicon nitride, or silicon oxynitride, and may be a single layer or multiple layers including the inorganic insulating material.

A source electrode S1 and/or a drain electrode D1 electrically connected to the first semiconductor layer A1 of the first transistor T1 may be disposed on the second interlayer insulating layer 107. A source electrode S6 and/or a drain electrode D6 electrically connected to the sixth semiconductor layer A6 of the sixth transistor T6 may be disposed on the second interlayer insulating layer 107. The source electrodes S1 and S6 and/or the drain electrodes D1 and D6 may include Al, Cu, and/or Ti, and may each be a multi-layer or single layer including the aforementioned materials.

A first organic insulating layer 109 may be disposed on the pixel circuit PC. The first organic insulating layer 109 may include an organic insulating material, such as acryl, benzocyclobutene (BCB), polyimide, or hexamethyldisiloxane (HMDSO).

A connection metal CM as a pattern among a plurality of patterns of a connection layer may be disposed on the first organic insulating layer 109. The connection metal CM may include Al, Cu, and/or Ti, and may be a multi-layer or single layer including the aforementioned materials.

A second organic insulating layer 111 may be disposed between the connection metal CM and the pixel electrode 210. The second organic insulating layer 111 may include an organic insulating material, such as acryl, benzocyclobutene (BCB), polyimide, or hexamethyldisiloxane (HMDSO). According to the embodiment described above with reference to FIG. 5A, the pixel circuit PC and the pixel electrode 210 are electrically connected to each other through, at or by the connection metal CM. However, according to another embodiment, the connection metal CM may be omitted, and one organic insulating layer may be positioned between the pixel circuit PC and the pixel electrode 210. Alternatively, three or more organic insulating layers may be positioned between the pixel circuit PC and the pixel electrode 210, and the pixel circuit PC and the pixel electrode 210 may be electrically connected to each other through a plurality of connection metals.

The pixel electrode 210 may be formed on the second organic insulating layer 111. The pixel electrode 210 may be formed to be a (semi)transparent electrode or a reflective electrode. When the pixel electrode 210 is formed (or provided) as a (semi)transparent electrode, the pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). When the pixel electrode 210 is formed as a reflective electrode, a reflective layer may be formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a layer formed of ITO, IZO, ZnO, or In₂O₃ may be formed on the reflective layer. According to an embodiment, the pixel electrode 210 may have a structure in which an ITO layer, an Ag layer, and an ITO layer are sequentially stacked. The pixel electrode 210 may be electrically connected to the connection metal CM through a contact hole of the second organic insulating layer 111. Herein, a contact hole may be defined by portions of a layer, such as by solid portions thereof. As such, a contact hole may be defined in such layer.

An electrode protective layer 113 may be formed on the pixel electrode 210. The electrode protective layer 113 may be patterned together with the pixel electrode 210. For example, the pixel electrode 210 and the electrode protective layer 113 may be formed using the same mask. Ends or edges of the pixel electrode 210 and the electrode protective layer 113 may coincide with or be aligned with each other, without being limited thereto. The electrode protective layer 113 may prevent the pixel electrode 210 from being damaged by a gas or liquid material used in various etching or ashing processes included in a process of providing a display apparatus 1.

The electrode protective layer 113 may have a thickness of about 250 angstroms (Å) to about 500 Å, but the disclosure is not limited thereto. The electrode protective layer 113 may include a material that may be selectively etched without damaging the pixel electrode 210 disposed under the material layer for forming the electrode protective layer 113. For example, the electrode protective layer 113 may include a conductive oxide such as indium zinc oxide (IZO) and/or indium gallium zinc oxide (IGZO).

Referring to FIG. 7B, an inorganic bank layer 310 and a metal bank layer 320 may be sequentially formed to cover the pixel electrode 210. The inorganic bank layer 310 and the metal bank layer 320 may extend along end surfaces or side surfaces of the pixel electrode 210, such as to cover the pixel electrode 210.

The inorganic bank layer 310 and the metal bank layer 320 may be entirely formed on the substrate 100, such as being provided along an entirety of the substrate 100 like an entirety of the top surface of the substrate 100. For example, the inorganic bank layer 310 may overlap the pixel electrode 210 and the electrode protective layer 113, and may directly contact a portion of an upper surface of the second organic insulating layer 111 on which the pixel electrode 210 and the electrode protective layer 113 do not exist. That is, a portion of the upper surface of the second organic insulating layer 111 may be exposed outside of the pixel electrode 210 and the electrode protective layer 113 to define an exposed portion of the second organic insulating layer 111, such that the inorganic bank layer 310 directly contacts the exposed portion. The inorganic bank layer 310 may include an inorganic insulating material, such as silicon oxide, silicon nitride, or silicon oxynitride, and may be a single layer or multiple layers including the inorganic insulating material.

The metal bank layer 320 may be entirely formed on the inorganic bank layer 310 (e.g., formed or provided on an entirety of the inorganic bank layer 310). The metal bank layer 320 may include a first metal bank layer 321 and a second metal bank layer 323 containing different metals, together with each other. The first metal bank layer 321 and the second metal bank layer 323 may include metals having different etch selectivities. For example, the first metal bank layer 321 may include aluminum (Al), and the second metal bank layer 323 may include titanium (Ti). The first metal bank layer 321 and the second metal bank layer 323 may form an interface therebetween.

The inorganic bank layer 310 and the metal bank layer 320 may each extend from the display area DA of FIG. 4, to the non-display area NDA of FIG. 4, and may overlap the common power supply line 16 of FIG. 4 which is in the non-display area NDA. In this case, the inorganic bank layer 310 may include (or define) an opening that overlaps the common power supply line 16 of FIG. 4 and exposes a portion of an upper surface of the common power supply line 16 of FIG. 4 to outside the inorganic bank layer 310. The first metal bank layer 321 of the metal bank layer 320 may directly contact the common power supply line 16 of FIG. 4 through or at the opening of the inorganic bank layer 310. In other words, the first metal bank layer 321 may be electrically connected to the common power supply line 16 of FIG. 4, in the non-display area NDA.

Referring to FIG. 7C, an organic bank layer 330 may be formed on the metal bank layer 320. According to an embodiment, the inorganic bank layer 310, the metal bank layer 320, and the organic bank layer 330 may together constitute a bank layer 300. The bank layer 300 may include both the solid material portions of the various sub-layers together with the openings defined by solid portions spaced apart from each other within the various sub-layers.

The organic bank layer 330 may have (or define) an opening that covers or corresponds to an edge of the pixel electrode 210 and overlaps the pixel electrode 210, when viewed in a direction substantially perpendicular to the upper surface of the substrate 100 (e.g., the plan view). A portion of an upper surface of the second metal bank layer 323 may be exposed to outside the organic bank layer 330 through the opening of the organic bank layer 330.

The organic bank layer 330 may have a black color. The organic bank layer 330 may include a light shielding material, and may have a black color to define a light blocking layer including light blocking patterns spaced apart from each other to define the opening of the organic bank layer 330. The light shielding material may include carbon black, carbon nanotubes, resin or paste including a black pigment, metal particles (e.g., nickel (Ni), aluminum (Al), molybdenum (Mo), and an alloy thereof), metal oxide particles (e.g., a chromium oxide), or metal nitride particles (e.g., a chromium nitride). When the organic bank layer 330 includes the light shielding material, external light reflection due to metal structures arranged under the organic bank layer 330 may be reduced.

Referring to FIG. 7D, using the organic bank layer 330 as a mask, a portion of the second metal bank layer 323, a portion of the first metal bank layer 321, and a portion of the inorganic bank layer 310 may be removed through the opening of the organic bank layer 330. For example, a portion of the second metal bank layer 323 overlapping the opening of the organic bank layer 330 may be removed to form a third sub-opening 323OP, a portion of the first metal bank layer 321 may be removed to form a second sub-opening 321OP, and a portion of the inorganic bank layer 310 may be removed to form a first sub-opening 310OP. The first sub-opening 310OP of the inorganic bank layer 310 may overlap a center portion of the pixel electrode 210, and a solid portion of the inorganic bank layer 310 which defines the first sub-opening 310OP may cover the edge of the pixel electrode 210.

According to an embodiment, the portion of the inorganic bank layer 310, the portion of the first metal bank layer 321, and the portion of the second metal bank layer 323 may be removed by dry etching. The first sub-opening 310OP, the second sub-opening 321OP, and the third sub-opening 323OP together with the opening in the organic bank layer 330 may overlap with one another to form a pixel opening OP that passes through the bank layer 300 and exposes the upper surface of the electrode protective layer 113 (or the pixel electrode 210 as including the electrode protective layer 113) to outside the bank layer 300. Boundaries of the first sub-opening 310OP, the second sub-opening 321OP, and the third sub-opening 323OP formed through dry etching may be substantially aligned with one another. In an embodiment, side surfaces of the inorganic bank layer 310, the first metal bank layer 321, the second metal bank layer 323 and the organic bank layer 330 which define the pixel opening OP may be coplanar with each other, without being limited thereto. During an etching process, the electrode protective layer 113 may protect the upper surface of the pixel electrode 210 below the electrode protective layer 113.

Referring to FIG. 7E, at least a portion of the electrode protective layer 113 may be removed from the pixel opening OP to expose the upper surface of the pixel electrode 210 to outside the bank layer 300 and outside the electrode protective layer 113. The at least a portion of the electrode protective layer 113 may be removed by wet etching. In an embodiment, for example, the providing of the pixel opening OP in the bank layer 300 may include removing a first portion of the electrode protective layer 113 and maintaining a second portion of the electrode protective layer 113 which is on the inorganic bank layer 310 and at an edge of the pixel electrode 210.

A portion of the electrode protective layer 113 may remain between the pixel electrode 210 and the inorganic bank layer 310. The remaining portion of the electrode protective layer 113 and the inorganic bank layer 310 may overlap the edge of the pixel electrode 210 to increase a distance between the pixel electrode 210 and the metal bank layer 320 as well as a distance between the pixel electrode 210 and an opposite electrode 230 of a light-emitting diode which will be described later, thereby preventing an electrical arc or the like from occurring between the pixel electrode 210 and the opposite electrode 230.

According to other embodiments, the electrode protective layer 113 may be completely removed. In this case, a groove that is formed by completely removing the electrode protective layer 113 interposed between the pixel electrode 210 and the inorganic bank layer 310 may remain empty in the display apparatus 1, or may be filled with an intermediate layer described later.

Thereafter, a portion of the first metal bank layer 321 may be removed through a wet etching process. Since the etching selectivity of the first metal bank layer 321 is different from that of the second metal bank layer 323, the second metal bank layer 323 may be hardly removed or very little removed while a portion of the first metal bank layer 321 is being removed. According to an embodiment, a process of removing at least a portion of the electrode protective layer 113 and a process of removing a portion of the first metal bank layer 321 may be performed simultaneously or sequentially.

A portion of the first metal bank layer 321 may be removed, and thus a width (or area) of the second sub-opening 321OP may be increased. Accordingly, the width (or area) of the second sub-opening 321OP may be larger than a width (or area) of the first sub-opening 310OP and a width (or area) of the third sub-opening 323OP. The width may be a planar dimension, such as a dimension in a direction along the substrate 100. The width of an opening may be defined between sidewalls or side surfaces of a layer which defines the opening.

The metal bank layer 320 may have an undercut structure in which a portion of the first metal bank layer 321 overlapping the second metal bank layer 323 is removed. For example, the second metal bank layer 323 may protrude from a lateral surface of the first metal bank layer 321 defining the pixel opening OP, to thereby form a tip PT. That is the second metal bank layer 323 may extend further from a side surface of the first metal bank layer 321, to define a protruded portion as the tip OT. In other words, the second metal bank layer 323 may have a tip PT extending from the upper surface of the first metal bank layer 321 toward a center portion of the pixel opening OP.

According to an embodiment, a protrusion length of the tip PT which is taken along the substrate 100, which is a length from a distal end of the tip PT of the second metal bank layer 323 to the lateral surface of the first metal bank layer 321 defining the pixel opening OP, may be about 2 micrometers (μm) or less. A length of the tip PT of the second metal bank layer 323 may be about 0.3 μm to about 1 μm, or about 0.3 μm to about 0.7 μm.

Referring to FIG. 7F, an intermediate layer 220 and an opposite electrode 230 may be formed to overlap the pixel electrode 210 at an exposed portion thereof within the structure described above with reference to FIG. 7E.

A stacked structure of the pixel electrode 210, the intermediate layer 220, and the opposite electrode 230 may together correspond to a light-emitting diode ED. According to some embodiments, the intermediate layer 220 may be formed through a deposition method such as thermal deposition. According to some embodiments, the opposite electrode 230 may be formed through a deposition method such as thermal deposition or sputtering.

The intermediate layer 220 may include an emission layer 222 as a light emission layer as shown in FIG. 7I. The intermediate layer 220 may include a functional layer interposed between the pixel electrode 210 and the emission layer 222 and/or between the emission layer 222 and the opposite electrode 230. A functional layer between the pixel electrode 210 and the emission layer 222 will now be referred to as a first functional layer 221, and a functional layer interposed between the emission layer 222 and the opposite electrode 230 will now be referred to as a second functional layer 223.

The emission layer 222 may include a low molecular or high molecular organic material that emits light of a certain color (red, green, or blue). According to another embodiment, the emission layer 222 may include an inorganic material or quantum dots.

The first functional layer 221 may include a hole transport layer (HTL) and/or a hole injection layer (HIL). The second functional layer 223 may include an electron transport layer (ETL) and/or an electron injection layer (EIL). The first functional layer 221 and the second functional layer 223 may include an organic material.

The intermediate layer 220 may have a single stack structure including a single emission layer, or a tandem structure that is a multi-stack structure including a plurality of emission layers. When the intermediate layer 220 has a tandem structure, a charge generation layer (CGL) may be disposed between a plurality of stacks.

According to an embodiment, the intermediate layer 220 may be formed entirely on the substrate 100 as shown in FIG. 7E. For example, the intermediate layer 220 may be deposited without separate masks, and thus a deposition material for forming the intermediate layer 220 may form a dummy intermediate layer 220b extending from the upper surface of the organic bank layer 330 to the lateral surface of the tip PT of the second metal bank layer 323. The intermediate layer 220 and the dummy intermediate layer 220b may be separated and spaced apart from each other by the tip PT. In an embodiment, the operation of providing of the intermediate layer 220 of the light-emitting element may include providing an intermediate layer material both on the pixel electrode 210 and on the bank layer 300, and the intermediate layer material which is on the pixel electrode 210 is separated from the intermediate layer material which is on the bank layer 300.

The intermediate layer 220 and the dummy intermediate layer 220b may include sub-layers (e.g., a first functional layer, an emission layer, and a second functional layer) in a same number and/or a same material. That is, the intermediate layer 220 and the dummy intermediate layer 220b may be in a same layer as each other. As being in a same layer, elements may be formed in a same process and/or include a same material as each other, elements may be respective portions or patterns of a same material layer, elements may be on a same layer by forming an interface with a same underlying or overlying layer, etc., without being limited thereto.

According to another embodiment, the emission layer 222 of the intermediate layer 220 may be patterned in correspondence with the pixel electrode 210. For example, the emission layer 222 may be formed to overlap the pixel electrode 210 by using a fine metal mask. The patterned emission layer 222 may include a plurality of emission layer patterns respectively corresponding to a plurality of pixel electrodes 210, without being limited thereto.

The opposite electrode 230 may include a conductive material having a low work function. For example, the opposite electrode 230 may include a (semi)transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. Alternatively, the opposite electrode 230 may further include a layer, such as ITO, IZO, ZnO, or In₂O₃, on the (semi)transparent layer including any of the above-described materials.

A capping layer CPL may be formed on the opposite electrode 230 as shown in FIG. 7I. The capping layer CPL of FIG. 7I may be a layer provided to protect the opposite electrode 230 and also increase light extraction efficiency. A refractive index of the capping layer CPL of FIG. 7I may be greater than that of the opposite electrode 230. Alternatively, the capping layer CPL of FIG. 7I may be a stack of layers having different refractive indexes. For example, the refractive index of the capping layer CPL of FIG. 7I may be about 1.7 to about 1.9. The capping layer CPL of FIG. 7I may include an organic material, and may additionally include an inorganic insulating material such as LiF.

The opposite electrode 230 may be entirely formed on the substrate 100. For example, the opposite electrode 230 may be deposited without separate masks, and thus a deposition material for forming the opposite electrode 230 may form a dummy opposite electrode 230b extending from the upper surface of the organic bank layer 330 and along the lateral surface of the tip PT of the second metal bank layer 323. The opposite electrode 230 and the dummy opposite electrode 230b may be separated and spaced apart from each other by the tip PT. The opposite electrode 230 and the dummy opposite electrode 230b may include sub-layers (e.g., a first functional layer, an emission layer, and a second functional layer) in a same number and/or a same material. That is, the opposite electrode 230 and the dummy opposite electrode 230b may be in a same layer as each other.

According to some embodiments, the intermediate layer 220 may be formed using a thermal deposition process, and the opposite electrode 230 may be formed using a sputtering process. The deposition material for forming the opposite electrode 230 may be incident in a more oblique direction than the deposition material for forming the intermediate layer 220, based on a direction perpendicular to the substrate 100. Thus, the deposition material of the opposite electrode 230 may be in direct contact with a lateral surface (e.g., a side surface) of the first metal bank layer 321 that is covered by the tip PT of the second metal bank layer 323 and thus has no intermediate layer 220 formed thereon. For example, as shown in FIG. 7F, the opposite electrode 230 may form a contact region 230CNT at which material of the opposite electrode 230 is in direct contact with a lateral surface of the first metal bank layer 321 beyond an area of the opposite electrode 230 which is covered by the intermediate layer 220. That is, within the pixel opening OP, the opposite electrode 230 extends further than the intermediate layer 220 to contact the side surface of the first metal bank layer 321. The contact region 230CNT may include a contact area which extends along the z direction, together with the x direction and/or the y direction (e.g., into the page for the views of FIGS. 7A to 7H). Where a lateral surface of the first metal bank layer 321 defines the pixel opening OP, the operation of providing the opposite electrode 230 directly contacts the opposite electrode 230 with the lateral surface of the first metal bank layer 321.

According to some embodiments, during a deposition process of the opposite electrode 230, the substrate 100 may be tilted at an angle to the incidence direction of the deposition material for forming the opposite electrode 230, so that the area of the contact region 230CNT where the opposite electrode 230 directly contacts the lateral surface of the first metal bank layer 321 is provided.

As described above, since the first metal bank layer 321 is electrically connected to the common power supply line 16 of FIG. 4, the opposite electrode 230 may receive the common voltage ELVSS through the first metal bank layer 321.

Referring to FIG. 7G, an encapsulation layer 500 including an inorganic encapsulation layer 510, a planarization layer 520, and a protective layer 530 may be formed on the layer of the opposite electrode 230.

The inorganic encapsulation layer 510 may include a light-transmitting inorganic material having a low refractive index, and may be formed by a method such as chemical vapor deposition. The light-transmitting inorganic material having a low refractive index may include silicon oxide, magnesium fluoride, and the like, and the inorganic encapsulation layer 510 may be a single layer or multi-layer including the aforementioned materials. The inorganic encapsulation layer 510 may have a first refractive index. For example, the first refractive index may be in the range of about 1.3 to about 1.6.

Since the inorganic encapsulation layer 510 has a relatively excellent step coverage, the inorganic encapsulation layer 510 may consecutively cover an upper surface of the dummy opposite electrode 230b, a lower surface of the tip PT of the second metal bank layer 323, the lateral surface of the first metal bank layer 321 defining the pixel opening OP, and the upper surface of the opposite electrode 230. Accordingly, the inorganic encapsulation layer 510 may directly contact the lower surface of the tip PT of the second metal bank layer 323 and the lateral surface of the first metal bank layer 321 to form an inorganic contact region. The inorganic contact region may form a closed loop that completely surrounds one light-emitting diode ED, thereby reducing or blocking a path through which impurities such as moisture and/or air permeate. In addition, adhesion of the inorganic encapsulation layer 510 may be improved due to irregularities of the tip PT. As being in contact, elements may form an interface therebetween.

The planarization layer 520 may be formed on the inorganic encapsulation layer 510. The planarization layer 520 may fill the pixel opening OP of the bank layer 300 to provide a flat base surface for the components disposed over the planarization layer 520. The base surface may be an upper surface or a top surface which is furthest from the pixel circuit PC (or the substrate 100) along the thickness direction (e.g., the z direction).

The planarization layer 520 may include a light-transmitting organic material having a high refractive index. The light-transmitting organic material having a high refractive index may be an acryl-based and/or siloxane-based organic material having a refractive index of about 1.6 or greater. According to an embodiment, the planarization layer 520 may be a single layer or multi-layer including the aforementioned materials.

The planarization layer 520 may include high-refractive particles distributed within the light-transmitting organic material. For example, the high-refractive particles may include zirconium oxide, zinc oxide, titanium oxide, niobium oxide, tantalum oxide, tin oxide, nickel oxide, silicon nitride, indium nitride, gallium nitride, and the like.

The planarization layer 520 may have a second refractive index greater than the first refractive index of the inorganic encapsulation layer 510. For example, the second refractive index may be in the range of about 1.6 to about 2.5. According to an embodiment, the planarization layer 520 may have a multi-layer structure including a plurality of layers having different refractive indexes.

The protective layer 530 may be formed on the planarization layer 520. The protective layer 530 may include at least one inorganic material from among aluminum oxide, titanium oxide, tantalum oxide, hafnium oxide, zinc oxide, silicon oxide, silicon nitride, and silicon oxynitride. The protective layer 530 may prevent damage to the planarization layer 520 in a subsequent process, and may provide a flat base surface to the components positioned on the protective layer 530. According to an embodiment, the protective layer 530 may have a third refractive index less than the second refractive index. For example, the third refractive index may be in the range of about 1.3 to about 1.6.

According to an embodiment, as shown in FIG. 7G, the planarization layer 520 may be formed to correspond to the pixel opening OP of the bank layer 300. The planarization layer 520 may fill the pixel opening OP, but may not overlap the upper surface of the bank layer 300. In this case, above the solid portion of the bank layer 300, the inorganic encapsulation layer 510 may directly contact the protective layer 530 to form an inorganic contact region. Therefore, even when a defect such as a crack occurs in the protective layer 530, propagation of impurities such as moisture to its neighboring pixels may be prevented or reduced.

According to another embodiment, the planarization layer 520 may be entirely formed on the inorganic encapsulation layer 510. In this case, the planarization layer 520 filling a plurality of pixel openings may be integrally formed, and may provide a flatter base surface.

Referring to FIG. 7H, the input sensing layer TU may be formed on the encapsulation layer 500.

According to an embodiment, the input sensing layer TU may include a first conductive layer CL1, a first intermediate insulating layer IL1, a second conductive layer CL2, and a second intermediate insulating layer IL2. The input sensing layer TU may be disposed directly on the protective layer 530.

For example, each of the first conductive layer CL1 and the second conductive layer CL2 may have a single-layered structure or a stacked multi-layered structure. A conductive layer having a single-layered structure may include a metal layer or a transparent conductive layer. The metal layer may include molybdenum, silver, titanium, copper, aluminum, and an alloy thereof. The transparent conductive layer may include a transparent conductive oxide such as indium tin oxide (ITO), indium zinc oxide (IZO), zinc oxide (ZnO), or indium tin zinc oxide (ITZO). Alternatively, the transparent conductive layer may include a conductive polymer (e.g., PEDOT), metal nano wires, graphene, or the like.

A conductive layer having a multi-layered structure may include a plurality of metal layers. The plurality of metal layers may have, for example, a three-layered structure of titanium/aluminum/titanium (Ti/Al/Ti). The conductive layer having a multi-layered structure may include at least one metal layer and at least one transparent conductive layer.

Each of the first conductive layer CL1 and the second conductive layer CL2 includes a plurality of patterns. The patterns may be spaced apart from each other, such as to form a gap therebetween. It may be hereinafter understood that the first conductive layer CL1 includes first conductive patterns and the second conductive layer CL2 includes second conductive patterns. The first conductive patterns and the second conductive patterns may form the various detection electrodes shown in FIG. 6. According to an embodiment, the detection electrode may have a mesh shape to prevent visual recognition of the detection electrode by a user. The conductive layers or conductive patterns described above may correspond to the solid portions of the various detection electrodes which form the mesh shape.

Each of the first intermediate insulating layer IL1 and the second intermediate insulating layer IL2 may have a single-layered or multi-layered structure. Each of the first intermediate insulating layer IL1 and the second intermediate insulating layer IL2 may include an inorganic insulating material and/or an organic insulating material. According to an embodiment, one of the first intermediate insulating layer IL1 and the second intermediate insulating layer IL2 may include an inorganic insulating material. The inorganic insulating material may include at least one of aluminum oxide, titanium oxide, silicon oxide, silicon oxynitride, zirconium oxide, and hafnium oxide. According to an embodiment, the first intermediate insulating layer IL1 and/or the second intermediate insulating layer IL2 may include an organic insulating material.

The anti-reflection layer PU may be formed on the input sensing layer TU. The polarization layer PU is a component for reducing the reflectance of external light, and may include a retarder and a polarizer. In FIG. 7H, the anti-reflection layer PU is directly disposed on the input sensing layer TU. However, according to some embodiments, the anti-reflection layer PU may be attached to the input sensing layer TU by an optically clear adhesion member OCA or the like.

The window layer WU may be disposed on the anti-reflection layer PU. The optically clear adhesion member OCA may be disposed between the anti-reflection layer PU and the window layer WU.

The display apparatus 1 may include a light-emission area provided in plural including a plurality of light-emission areas. The bank layer 300 may define the light-emission area corresponding to a pixel opening OP. The light-emission area may be a planar area of a pixel area. The pixel area may include the light-emission area together with a non-light emission area adjacent to the light emission area, without being limited thereto.

While FIG. 7H shows the organic bank layer 330 remaining in the display apparatus 1, the embodiments are not limited thereto. In an embodiment, between the providing of the pixel opening OP of the bank layer 300 (FIG. 7D) and the providing of the intermediate layer 220 of the light-emitting element (FIG. 7F), the organic bank layer 330 may be removed. Where the organic bank layer 330 is removed, the intermediate layer 220 in FIG. 7H may be provided on the second metal bank layer 323.

According to embodiments, light emitted by the light-emitting diode ED may travel along a first path L1 substantially perpendicular to the upper surface of the substrate 100, or may travel along a second path L2 which is oblique or inclined relative to a direction substantially perpendicular to the upper surface of the substrate 100. Due to a difference between the respective refractive indexes of the planarization layer 520 and the inorganic encapsulation layer 510, the light traveling along the second path L2 may be refracted or totally reflected by (or at) an interface between the inorganic encapsulation layer 510 and the planarization layer 520, and thus may travel along a third path L3 substantially perpendicular to the upper surface of the substrate 100. Accordingly, front surface extraction efficiency of the light emitted by the light-emitting diode ED may be improved, leading to an improvement in the front surface visibility of the display apparatus 1.

According to a comparative example, when a second refractive index of a comparative planarization layer is equal to or less than a first refractive index of a comparative inorganic encapsulation layer, a separate optical functional layer is disposed to improve the front surface extraction efficiency of light emitted by a light-emitting diode. The optical functional layer complicates a process of manufacturing or providing a display apparatus 1 and increases the thickness of the display apparatus 1. The display apparatus 1 according to one or more embodiment may have high light extraction efficiency while reducing an overall thickness of the display apparatus 1 by omitting the optical functional layer of the comparative structure for improving front surface extraction efficiency of light.

FIG. 7H illustrates a display apparatus 1 in which an organic bank layer 330 is located on the metal bank layer 320, but the organic bank layer 330 may be omitted from the display apparatus 1. According to an embodiment, as described with reference to FIG. 7D, using the organic bank layer 330 as a mask, a portion of the second metal bank layer 323, a portion of the first metal bank layer 321, and a portion of the inorganic bank layer 310 may be removed through the opening of the organic bank layer 330, and then the organic bank layer 330 may be removed. Where the organic bank layer 330 is removed, the intermediate layer 220 may be provided on the second metal bank layer 323

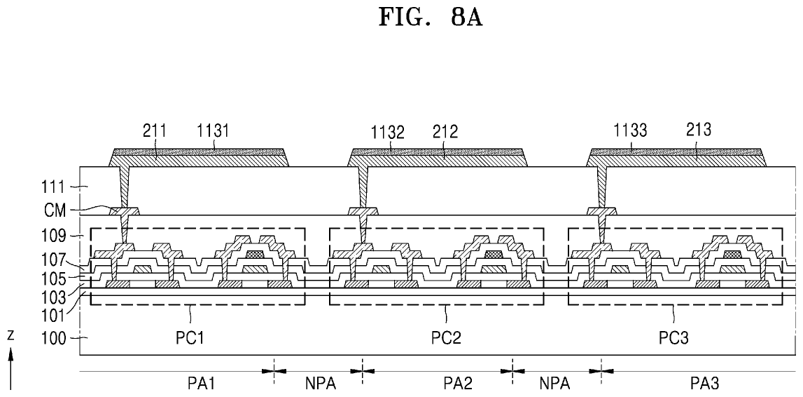

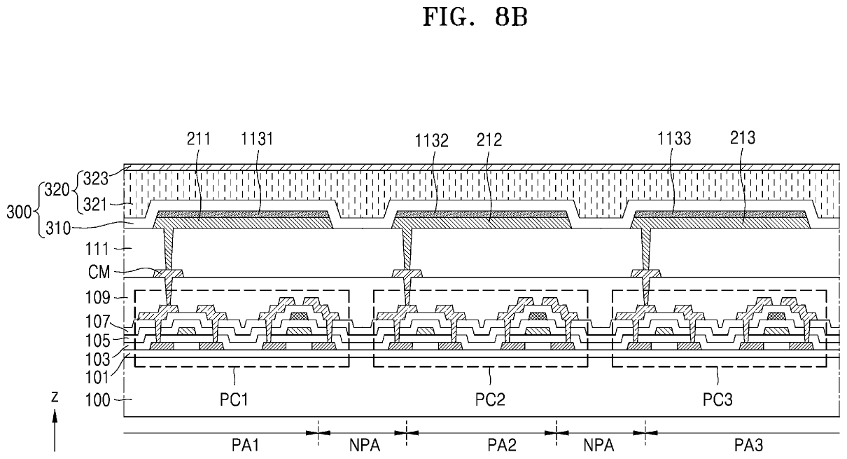

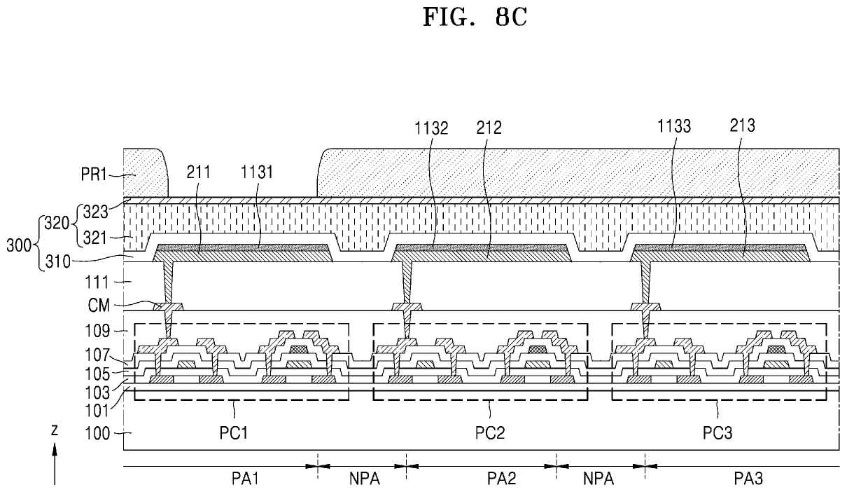

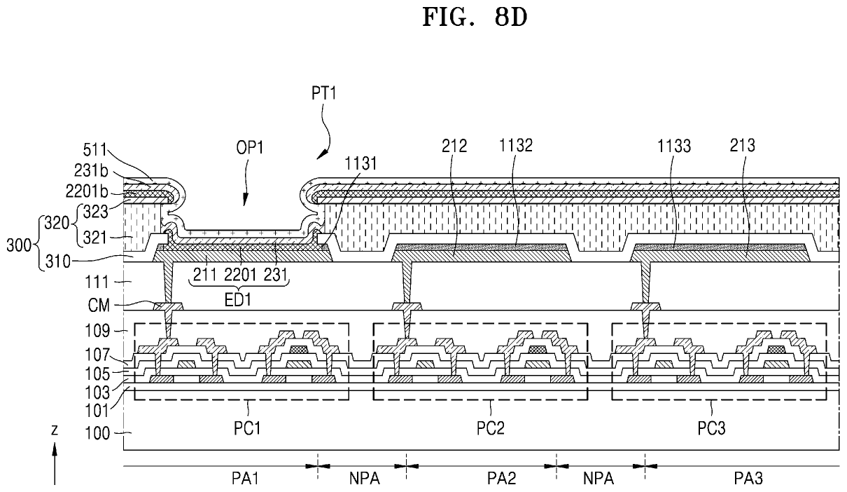

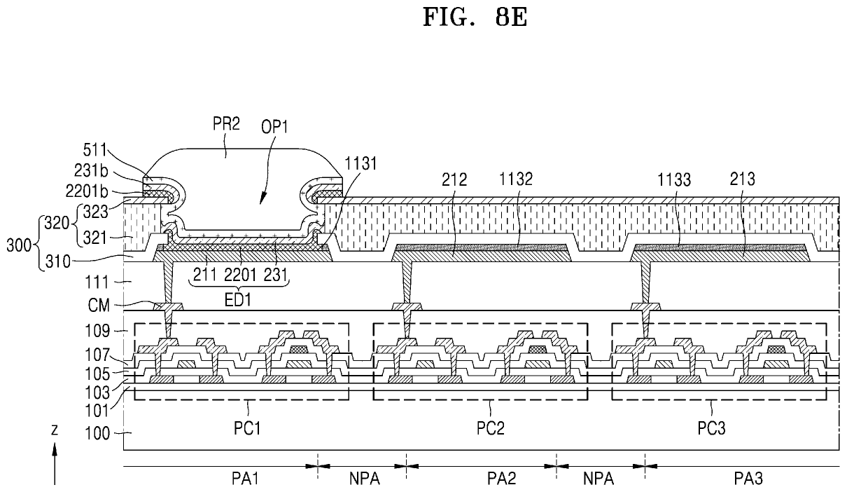

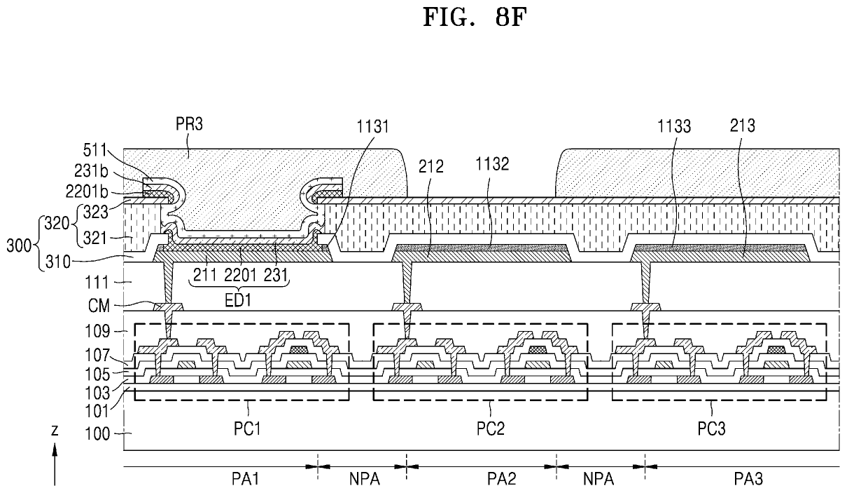

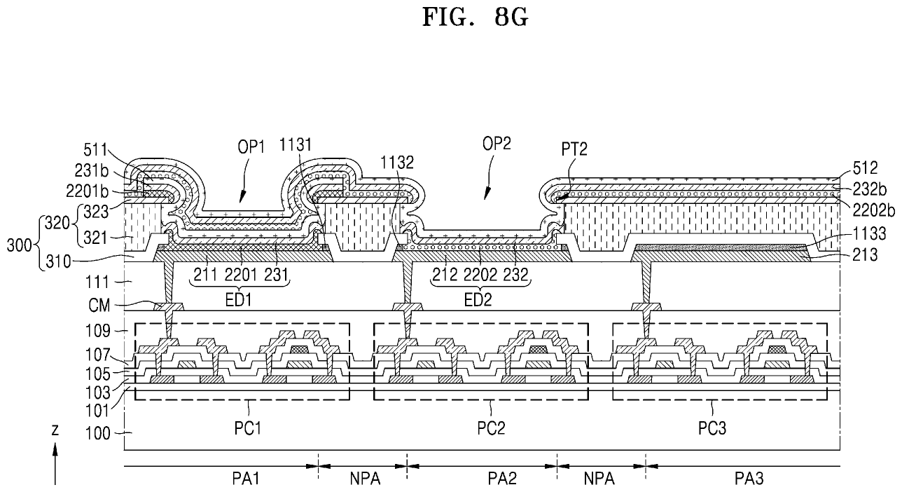

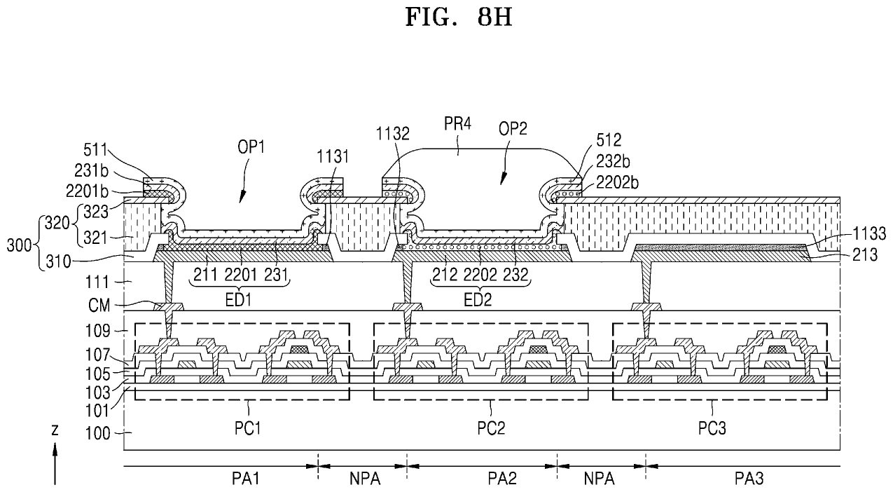

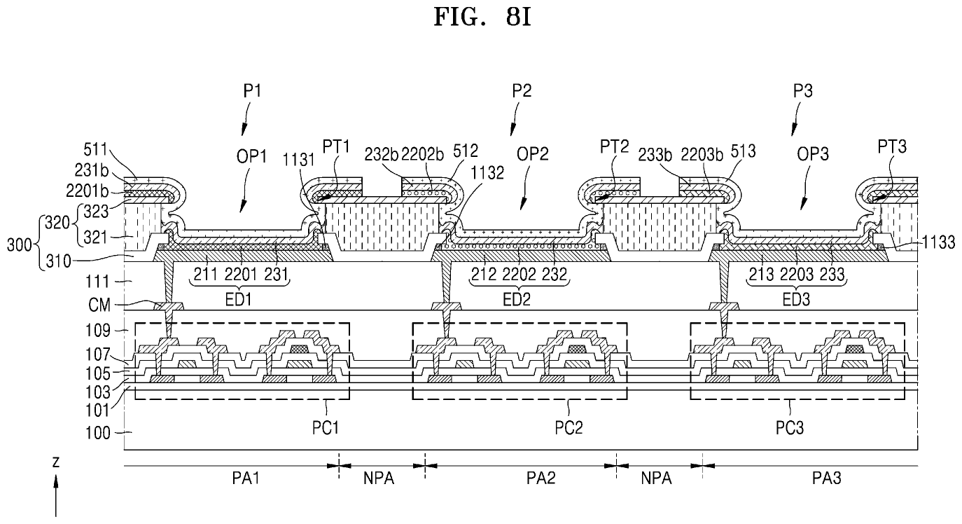

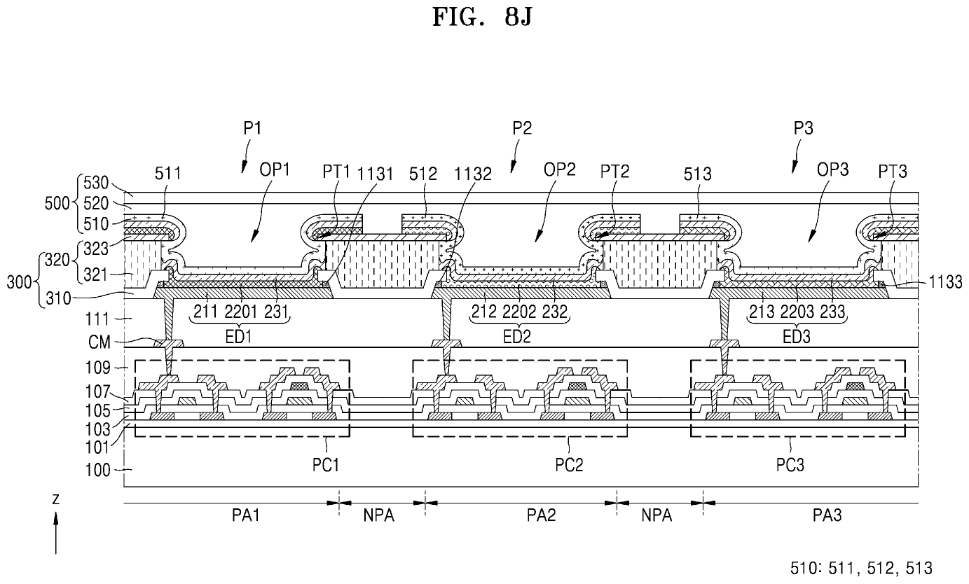

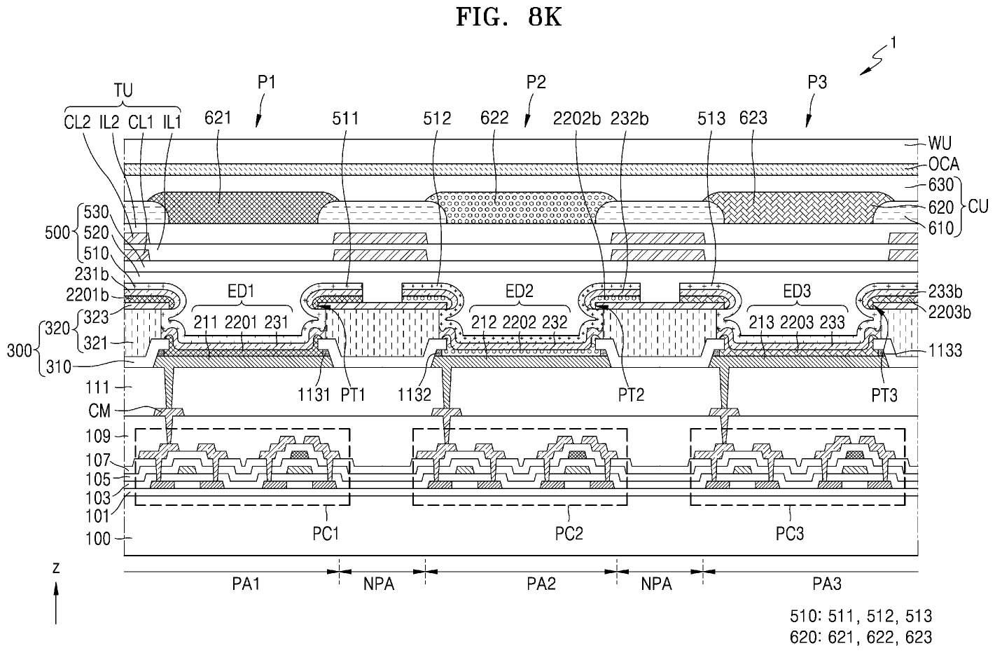

FIGS. 8A through 8K are schematic cross-sectional views of operations of a method of manufacturing a display apparatus 1, according to an embodiment.

Referring to FIG. 8A, a first pixel electrode 211, a second pixel electrode 212, and a third pixel electrode 213 as a plurality of pixel electrodes in a pixel electrode layer are formed on a substrate 100. The first pixel electrode 211, the second pixel electrode 212, and the third pixel electrode 213 may be disposed in a first pixel area PA1, a second pixel area PA2, and a third pixel area PA3, respectively, and may be spaced apart from one another in a direction along the substrate 100.

Before the first pixel electrode 211, the second pixel electrode 212, and the third pixel electrode 213 are formed, a first pixel circuit PC1, a second pixel circuit PC2, and a third pixel circuit PC3 may be formed on the substrate 100. According to an embodiment, the first pixel circuit PC1, the second pixel circuit PC2, and the third pixel circuit PC3 may have the same structures as the pixel circuit PC described above with reference to FIG. 7A.

The substrate 100 may include a glass material or polymer resin. The substrate 100 may have a structure in which a base layer including a polymer resin and an inorganic barrier layer are stacked.

A buffer layer 101 may be disposed on the upper surface of the substrate 100 to prevent impurities from permeating into a semiconductor layer of a transistor. The first pixel circuit PC1, the second pixel circuit PC2, and the third pixel circuit PC3 may be disposed on the buffer layer 101, and a first gate insulating layer 103 between a semiconductor layer and a gate electrode, a first interlayer insulating layer 105 between a lower electrode and an upper electrode of a storage capacitor Cst, and a second interlayer insulating layer 107 for insulating the source/drain electrode layer and the gate electrode layer of the transistor layer from each other may be formed.

A first organic insulating layer 109 and a second organic insulating layer 111 may be formed on the first pixel circuit PC1, the second pixel circuit PC2, and the third pixel circuit PC3. The first pixel electrode 211, the second pixel electrode 212, and the third pixel electrode 213 may be electrically connected to the first pixel circuit PC1, the second pixel circuit PC2, and the third pixel circuit PC3, respectively, via connection metals CM disposed between the first organic insulating layer 109 and the second organic insulating layer 111.

The first pixel electrode 211, the second pixel electrode 212, and the third pixel electrode 213 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent conductive layer formed of ITO, IZO, ZnO, or In2O3. According to some embodiments, the first pixel electrode 211, the second pixel electrode 212, and the third pixel electrode 213 may each have a structure in which an ITO layer, an Ag layer, and an ITO layer are sequentially stacked.

A first electrode protective layer 1131 may be formed on the first pixel electrode 211, a second electrode protective layer 1132 may be formed on the second pixel electrode 212, and a third electrode protective layer 1133 may be formed on the third pixel electrode 213. The first pixel electrode 211, the second pixel electrode 212, and the third pixel electrode 213 may be patterned together with the first electrode protective layer 1131, the second electrode protective layer 1132, and the third electrode protective layer 1133. The first electrode protective layer 1131, the second electrode protective layer 1132, and the third electrode protective layer 1133 may prevent the first pixel electrode 211, the second pixel electrode 212, and the third pixel electrode 213 from being damaged by a gas or liquid material used in various etching or ashing processes included in a display apparatus manufacturing process. The first electrode protective layer 1131, the second electrode protective layer 1132, and the third electrode protective layer 1133 may include a conductive oxide such as indium zinc oxide (IZO) and/or indium gallium zinc oxide (IGZO).

Referring to FIG. 8B, an inorganic bank layer 310 and a metal bank layer 320 which includes a first metal bank layer 321 together with a second metal bank layer 323 may be sequentially formed on each of the first electrode protective layer 1131, the second electrode protective layer 1132, and the third electrode protective layer 1133. The inorganic bank layer 310 and the metal bank layer 320 may be entirely formed on the substrate 100.

The inorganic bank layer 310 may include an inorganic insulating material, such as silicon oxide, silicon nitride, or silicon oxynitride, and may be a single layer or multiple layers including the inorganic insulating material.

The metal bank layer 320 may be entirely formed on the inorganic bank layer 310.

The metal bank layer 320 may include a first metal bank layer 321 and a second metal bank layer 323 containing different metals from each other. The first metal bank layer 321 and the second metal bank layer 323 may include metals having different etch selectivities. For example, the first metal bank layer 321 may include aluminum (Al), and the second metal bank layer 323 may include titanium (Ti). The first metal bank layer 321 may be electrically connected to the common power supply line 16 of FIG. 4. For example, the first metal bank layer 321 of the metal bank layer 320 may directly contact the common power supply line 16 of FIG. 4 through the opening of the inorganic bank layer 310.

Referring to FIG. 8C, a first photoresist PR1 may be formed on the metal bank layer 320. A material for forming the first photoresist PR1 may be entirely formed on the metal bank layer 320. The first photoresist PR1 may include solid portions which define an opening that overlaps the first pixel electrode 211, when viewed in a direction substantially perpendicular to the upper surface of the substrate 100, and may cover an edge of the first pixel electrode 211. A portion of an upper surface of the second metal bank layer 323 may be exposed to outside the photoresist layer including the first photoresist PR1, through the opening of the first photoresist PR1.

Referring to FIG. 8D, using the first photoresist PR1 as a mask, a portion of the second metal bank layer 323, a portion of the first metal bank layer 321, and a portion of the inorganic bank layer 310 may be removed through the opening of the first photoresist PR1.

According to an embodiment, the portion of the inorganic bank layer 310, the portion of the first metal bank layer 321, and the portion of the second metal bank layer 323 may be removed by dry etching to form a first pixel opening OP1 passing through the bank layer 300 and exposing a portion of the upper surface of the first electrode protective layer 1131 to outside the bank layer 300. During an etching process, the electrode protective layer 113 may protect the upper surface of the first pixel electrode 211 below the electrode protective layer 113.

At least a portion of the first electrode protective layer 1131 may be removed to expose the upper surface of the first pixel electrode 211 to outside the bank layer 300. The at least a portion of the first electrode protective layer 1131 may be removed by wet etching. According to an embodiment, a portion of the first electrode protective layer 1131 may remain between the inorganic bank layer 310 and the first pixel electrode 211.

A portion of the first metal bank layer 321 may be removed through a wet etching process. Due to the etching selectivity of the first metal bank layer 321 being different from that of the second metal bank layer 323, the second metal bank layer 323 may be hardly removed or very little removed while a portion of the first metal bank layer 321 is being removed.

The metal bank layer 320 may have or define an undercut structure in which a portion of the first metal bank layer 321 overlapping the second metal bank layer 323 is removed. For example, the second metal bank layer 323 may protrude further than a lateral surface of the first metal bank layer 321 defining the first pixel opening OP1, to thereby form a first tip PT1. In other words, the second metal bank layer 323 may have a first tip PT1 extending from an edge where the upper surface and the lateral surface of the first metal bank layer 321 meet each other, and in a direction toward a center portion of the first pixel opening OP1.

Thereafter, the first photoresist PR1 may be removed.

While FIG. 7H shows the organic bank layer 330 remaining in the display apparatus 1, the embodiments are not limited thereto. In an embodiment, the structure of the first photoresist PR1 may correspond to the organic bank layer 330 in FIG. 7C. In an embodiment, between the providing of the pixel opening OP of the bank layer 300 (FIG. 7D) and the providing of the intermediate layer 220 of the light-emitting element (FIG. 7F), the organic bank layer 330 may be removed, similar to removal of the first photoresist PR1 between processes shown in FIGS. 8C and 8D and described above. Where the organic bank layer 330 is removed, the intermediate layer 220 in FIG. 7H may be provided on the second metal bank layer 323, similar to how a respective intermediate layer is provided on the second metal bank layer 323 in FIG. 8D.

A first intermediate layer 2201 and a first opposite electrode 231 may be formed to overlap the first pixel electrode 211. A stack structure of the first pixel electrode 211, the first intermediate layer 2201, and the first opposite electrode 231 together corresponds to a first light-emitting diode ED1.

The first intermediate layer 2201 may include an emission layer that emits light of a first color. The first intermediate layer 2201 may have a structure similar to or the same as that described above with reference to FIG. 7I.

The first intermediate layer 2201 may be entirely formed on the substrate 100, such as to be in each of the pixel areas. For example, the first intermediate layer 2201 may be deposited without separate masks, and thus a first dummy intermediate layer 2201b extending from the upper surface of the second metal bank layer 323 to the lateral surface of the first tip PT1 may be formed. For example, the first dummy intermediate layer 2201b may be positioned in a non-pixel area NPA which is adjacent to the pixel area, in a second pixel area PA2 and in a third pixel area PA3. The first intermediate layer 2201 and the first dummy intermediate layer 2201b may be separated and spaced apart from each other by the first tip PT1. That is, the first intermediate layer 2201 and the first dummy intermediate layer 2201b may be disconnected from each other at the first pixel opening OP1 as shown in FIG. 8D.

The first opposite electrode 231 may include a (semi)transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. Alternatively, the first opposite electrode 231 may further include a layer, such as ITO, IZO, ZnO, or In₂O₃, on the (semi)transparent layer including any of the above-described materials.

The capping layer CPL of FIG. 7I may be formed on the first opposite electrode 231 as shown in FIG. 7I. The capping layer CPL of FIG. 7I may be a layer provided to protect the opposite electrode 230 and also increase light extraction efficiency. The capping layer CPL of FIG. 7I may include an organic material, and may additionally include an inorganic insulating material such as LiF.

The first opposite electrode 231 may be entirely formed on the first intermediate layer 2201. For example, a deposition material for forming the first opposite electrode 231 may form a first dummy opposite electrode 231b extending from an upper surface of the first dummy intermediate layer 2201b to the lateral surface of the first tip PT1. The first opposite electrode 231 and the first dummy opposite electrode 231b may include sub-layers in a same number and/or a same material. The first opposite electrode 231 and the first dummy opposite electrode 231b may be disconnected from each other at the first pixel opening OP1 as shown in FIG. 8D.

According to some embodiments, the first intermediate layer 2201 may be formed using a thermal deposition process, and the first opposite electrode 231 may be formed using a sputtering process. Thus, the first opposite electrode 231 may be in direct contact with a lateral surface of the first metal bank layer 321 that is covered by the first tip PT1 of the second metal bank layer 323 and thus has no first intermediate layer 2201 formed thereon.

As described above, since the first metal bank layer 321 is electrically connected to the common power supply line 16 of FIG. 4, the first opposite electrode 231 may receive the common voltage ELVSS through the first metal bank layer 321.

Thereafter, a first inorganic encapsulation layer 511 may be formed on the first opposite electrode 231. The first inorganic encapsulation layer 511 may have a first refractive index. For example, the first refractive index may be in the range of about 1.3 to about 1.6.

Since the first inorganic encapsulation layer 511 has a relatively excellent step coverage, the first inorganic encapsulation layer 511 may consecutively cover an upper surface of the first dummy opposite electrode 231b, a lower surface of the first tip PT1 of the second metal bank layer 323, the lateral surface of the first metal bank layer 321, and the upper surface of the first opposite electrode 231. Thus, the first inorganic encapsulation layer 511 may form an inorganic contact region that completely surrounds the first light-emitting diode ED1, thereby reducing or blocking a path through which impurities such as moisture and/or air permeate.

Referring to FIG. 8E, a second photoresist PR2 of a photoresist layer may be formed to correspond to the first pixel opening OP1 of the bank layer 300. The second photoresist PR2 may fill the first pixel opening OP1 and may extend out of the first pixel opening OP1 to be over the first dummy opposite electrode 231b of the non-pixel area NPA. According to an embodiment, respective portions of the first dummy intermediate layer 2201b and the first dummy opposite electrode 231b may be removed by using the second photoresist PR2 as a mask. In FIG. 8E, an edge of the second photoresist PR2 is adjacent to a boundary or edge of the first pixel opening OP1. However, a width (or area) of a region where the second photoresist PR2 is formed may be changed.

According to another embodiment, a process of forming the second photoresist PR2 and removing the respective portions of the first dummy intermediate layer 2201b and the first dummy opposite electrode 231b by using the second photoresist PR2 may be omitted. In this case, the first dummy intermediate layer 2201b and the first dummy opposite electrode 231b may be positioned in the non-pixel area NPA of a completed display apparatus 1.

Referring to FIG. 8F, a third photoresist PR3 of a photoresist layer may be formed on the stacked structure described above with reference to FIG. 8E. The third photoresist PR3 may be entirely formed on the metal bank layer 320 and the first inorganic encapsulation layer 511. The third photoresist PR3 may have an opening that overlaps the second pixel electrode 212, when viewed in a direction substantially perpendicular to the upper surface of the substrate 100, and may cover an edge of the second pixel electrode 212. A portion of an upper surface of the second metal bank layer 323 may be exposed to outside the photoresist layer through the opening of the third photoresist PR3.

Thereafter, using the third photoresist PR3 as a mask, a portion of the second metal bank layer 323, a portion of the first metal bank layer 321, and a portion of the inorganic bank layer 310 may be removed through the opening of the third photoresist PR3.

Referring to FIG. 8G, a second pixel opening OP2 passing through the bank layer 300 may be formed, and at least a portion of the second electrode protective layer 1132 may be removed.

An undercut structure in which a portion of the first metal bank layer 321 overlapping the second metal bank layer 323 is removed may be formed using a difference between the respective etching selectivities of the first metal bank layer 321 and the second metal bank layer 323. For example, the second metal bank layer 323 may have a second tip PT2 extending from the upper surface of the first metal bank layer 321 toward a center portion of the second pixel opening OP2.

Thereafter, the third photoresist PR3 may be removed.

A second intermediate layer 2202 and a second opposite electrode 232 may be formed to overlap the second pixel electrode 212. A stack structure of the second pixel electrode 212, the second intermediate layer 2202, and the second opposite electrode 232 together corresponds to a second light-emitting diode ED2.

The second intermediate layer 2202 may include an emission layer that emits light of a second color different from the first color. The second intermediate layer 2202 may be entirely formed on the substrate 100. For example, a deposition material for forming the second intermediate layer 2202 may be deposited without separate masks to form a second dummy intermediate layer 2202b extending from the upper surface of the second metal bank layer 323 to the lateral surface of the second tip PT2. For example, the second dummy intermediate layer 2202b may be positioned in the non-pixel area NPA, the first pixel area PA1, and the third pixel area PA3. The second intermediate layer 2202 and the second dummy intermediate layer 2202b may be separated and spaced apart from each other by the second tip PT2.

The second opposite electrode 232 may have a structure similar to or the same as the first opposite electrode 231 described above with reference to FIG. 8D.

The second opposite electrode 232 may be entirely formed on the second intermediate layer 2202. For example, a deposition material for forming the second opposite electrode 232 may form a second dummy opposite electrode 232b extending from an upper surface of the second dummy intermediate layer 2202b to the lateral surface of the second tip PT2. The second opposite electrode 232 and the second dummy opposite electrode 232b may include sub-layers in a same number and/or a same material.

According to some embodiments, the second intermediate layer 2202 may be formed using a thermal deposition process, and the second opposite electrode 232 may be formed using a sputtering process. Thus, the second opposite electrode 232 may be in direct contact with a lateral surface of the first metal bank layer 321 that is covered by the second tip PT2 of the second metal bank layer 323 and thus has no second intermediate layer 2202 formed thereon.

As described above, since the first metal bank layer 321 is electrically connected to the common power supply line 16 of FIG. 2, the second opposite electrode 232 may receive the common voltage ELVSS through the first metal bank layer 321.

Thereafter, a second inorganic encapsulation layer 512 may be formed on the second opposite electrode 232. The second inorganic encapsulation layer 512 may have a first refractive index. For example, the first refractive index may be in the range of about 1.3 to about 1.6.

Since the second inorganic encapsulation layer 512 has a relatively excellent step coverage, the second inorganic encapsulation layer 512 may consecutively cover an upper surface of the second dummy opposite electrode 232b, a lower surface of the second tip PT2 of the second metal bank layer 323, the lateral surface of the first metal bank layer 321, and the upper surface of the second opposite electrode 232. Thus, the second inorganic encapsulation layer 512 may form an inorganic contact region that completely surrounds the second light-emitting diode ED2, thereby reducing or blocking a path through which impurities such as moisture and/or air permeate.

Referring to FIG. 8H, a fourth photoresist PR4 may be formed to correspond to the second pixel opening OP2 of the bank layer 300. The fourth photoresist PR4 may fill the second pixel opening OP2 and may extend to over the second dummy opposite electrode 232b of the non-pixel area NPA. According to an embodiment, respective portions of the second dummy intermediate layer 2202b and the second dummy opposite electrode 232b may be removed using the fourth photoresist PR4 as a mask. In FIG. 8H, an edge of the fourth photoresist PR4 is adjacent to the boundary of the second pixel opening OP2, so that the first dummy intermediate layer 2201b and the second dummy intermediate layer 2202b are spaced apart from each other, the first dummy opposite electrode 231b and the second dummy opposite electrode 232b are spaced apart from each other, and the first inorganic encapsulation layer 511 and the second inorganic encapsulation layer 512 are spaced apart from each other. However, the disclosure is not limited thereto. For example, the width (or area) of a region where the second photoresist PR2 is formed may be changed. According to some embodiments, on the non-pixel area NPA, a portion of a stack structure of the first dummy intermediate layer 2201b, the first dummy opposite electrode 231b, and the first inorganic encapsulation layer 511 may overlap a portion of a stack structure of the second dummy intermediate layer 2202b, the second dummy opposite electrode 232b, and the second inorganic encapsulation layer 512.

Referring to FIG. 8I, similar to the manufacturing process of the first light-emitting diode ED1 and the first inorganic encapsulation layer 511 described above with reference to FIGS. 8A through 8E, the third light-emitting diode ED3 and the third inorganic encapsulation layer 513 may be formed.

For example, a third pixel opening OP3 may be formed to pass through the bank layer 300 and overlap the third pixel electrode 213. A portion of the third electrode protective layer 1133 may be located between the third pixel electrode 213 and the inorganic bank layer 310.

The second metal bank layer 323 may have a third tip PT3 extending from the upper surface of the first metal bank layer 321 toward a center portion of the third pixel opening OP3.

A third intermediate layer 2203 and a third opposite electrode 233 may be formed to overlap the third pixel electrode 213. A stack structure of the third pixel electrode 213, the third intermediate layer 2203, and the third opposite electrode 233 together corresponds to a third light-emitting diode ED3.

The third intermediate layer 2203 may include an emission layer that emits light of a third color different from the first and second colors. A third dummy intermediate layer 2203b may be formed on an upper surface of the second metal bank layer 323 adjacent to the third pixel opening OP3. The third intermediate layer 2203 and the third dummy intermediate layer 2203b may include sub-layers in a same number and/or a same material. The third intermediate layer 2203 and the third dummy intermediate layer 2203b may be separated and spaced apart from each other by the third tip PT3.

The third opposite electrode 233 may be formed on the third intermediate layer 2203, and the third dummy opposite electrode 233b may be formed on the third dummy intermediate layer 2203b. The third opposite electrode 233 and the third dummy opposite electrode 233b may include sub-layers in a same number and/or a same material. The third opposite electrode 233 and the third dummy opposite electrode 233b may be separated and spaced apart from each other by the third tip PT3.

According to some embodiments, the third intermediate layer 2203 may be formed using a thermal deposition process, and the third opposite electrode 233 may be formed using a sputtering process. Thus, the third opposite electrode 233 may be in direct contact with a lateral surface of the first metal bank layer 321 that is covered by the third tip PT3 of the second metal bank layer 323 and thus has no third intermediate layer 2203 formed thereon.

As described above, since the first metal bank layer 321 is electrically connected to the common power supply line 16 of FIG. 2, the third opposite electrode 233 may receive the common voltage ELVSS through the first metal bank layer 321.

Thereafter, a third inorganic encapsulation layer 513 may be formed on the third opposite electrode 233. The third inorganic encapsulation layer 513 may have a first refractive index. For example, the first refractive index may be in the range of about 1.3 to about 1.6.

Since the third inorganic encapsulation layer 513 has a relatively excellent step coverage, the third inorganic encapsulation layer 513 may consecutively cover an upper surface of the third dummy opposite electrode 233b, a lower surface of the third tip PT3 of the second metal bank layer 323, the lateral surface of the first metal bank layer 321, and the upper surface of the third opposite electrode 233. Thus, the third inorganic encapsulation layer 513 may form an inorganic contact region that completely surrounds the third light-emitting diode ED3, thereby reducing or blocking a path through which impurities such as moisture and/or air permeate.

Even though patterns may be formed in different processes, such patterns may be considered as in a same layer as each other. For example, patterns 231, 232 and 233 (and dummy patterns thereof) may be respective patterns of a common electrode layer. Similarly, patterns 511, 512 and 513 may be respective patterns of a lower inorganic encapsulation layer, for example, the inorganic encapsulation layer 510 (as indicated at the bottom of FIG. 8J).

Referring to FIG. 8J, a planarization layer 520 may be formed on the structure described above with reference to FIG. 8I. The planarization layer 520 may fill the pixel opening OP of the bank layer 300 to provide a flat base surface to the components disposed over the planarization layer 520.

The planarization layer 520 may include a light-transmitting organic material having a high refractive index. The light-transmitting organic material having a high refractive index may be an acryl-based and/or siloxane-based organic material having a refractive index of about 1.6 or greater. According to an embodiment, the planarization layer 520 may be a single layer or multi-layer including the aforementioned materials. The planarization layer 520 may include high-refractive particles distributed within the light-transmitting organic material.

The planarization layer 520 may have a second refractive index greater than the first refractive index of the inorganic encapsulation layer 510. For example, the second refractive index may be in the range of about 1.6 to about 2.5. According to an embodiment, the planarization layer 520 may have a multi-layer structure including a plurality of layers having different refractive indexes.

The protective layer 530 may be formed on the planarization layer 520. The protective layer 530 may include at least one inorganic material from among aluminum oxide, titanium oxide, tantalum oxide, hafnium oxide, zinc oxide, silicon oxide, silicon nitride, and silicon oxynitride.

In FIG. 8J, the planarization layer 520 fills the first pixel opening OP1, the second pixel opening OP2, and the third pixel opening OP3 and is integrally formed to be continuous across the various pixel areas and non-pixel area NAP. However, the disclosure is limited thereto. As described above with reference to FIG. 7G, the planarization layer 520 may fill each of the first pixel opening OP1, the second pixel opening OP2, and the third pixel opening OP3, but may not overlap the non-pixel area NPA. As not overlapping, elements may be adjacent to each other or spaced apart from each other along a planar direction.

The inorganic encapsulation layer 510 collectively includes patterns of the first inorganic encapsulation layer 511, the second inorganic encapsulation layer 512, and the third inorganic encapsulation layer 513, and the inorganic encapsulation layer 510, the planarization layer 520, and the protective layer 530 correspond to the encapsulation layer 500.

Referring to FIG. 8K, the input sensing layer TU may be formed on the encapsulation layer 500.

According to an embodiment, the input sensing layer TU may include the first conductive layer CL1, the first intermediate insulating layer IL1, the second conductive layer CL2, and the second intermediate insulating layer IL2. The input sensing layer TU may be disposed directly on the protective layer 530.

For example, each of the first conductive layer CL1 and the second conductive layer CL2 may have a single-layered structure or a stacked multi-layered structure. Each of the first conductive layer CL1 and the second conductive layer CL2 includes a plurality of patterns. It may be hereinafter understood that the first conductive layer CL1 includes first conductive patterns and the second conductive layer CL2 includes second conductive patterns. The first conductive layer CL1 and the second conductive layer CL2 may be located in the non-pixel area NPA.

Each of the first intermediate insulating layer IL1 and the second intermediate insulating layer IL2 may have a single-layered or multi-layered structure. Each of the first intermediate insulating layer IL1 and the second intermediate insulating layer IL2 may include an inorganic insulating material and/or an organic insulating material.

The color filter layer CU may be formed on the input sensing layer TU. The color filter layer CU may be disposed directly on the input sensing layer TU. According to some embodiments, the second intermediate insulating layer IL2 of the input sensing layer TU may be omitted, and the color filter layer CU may be directly disposed on the second conductive layer CL2 and the first intermediate insulating layer IL1.

The color filter layer CU may include a light-shielding layer 610, a color filter layer 620, and an overcoat layer 630. The color filter layer CU may reduce reflectivity of light (external light) that is incident from an external source toward the display apparatus.

The light-shielding layer 610 may have of define filter openings corresponding to the first pixel opening OP1, the second pixel opening OP2, and the third pixel opening OP3. The light-shielding layer 610 may include a black pigment. The light-shielding layer 610 may be a black matrix. Accordingly, reflection of the light (external light) incident from an external source toward the display apparatus 1 by the second metal bank layer 323, the first conductive layer CL1, and the second conductive layer CL2 may be blocked or reduced.

The color filter layer 620 may include a first color filter 621, a second color filter 622, and a third color filter 623. The first color filter 621, the second color filter 622, and the third color filter 623 may selectively transmit light beams respectively emitted by the first light-emitting diode ED1, the second light-emitting diode ED2, and the third light-emitting diode ED3 respectively positioned under the first color filter 621, the second color filter 622, and the third color filter 623, respectively. For example, when the first intermediate layer 2201 emits red light, the first color filter 621 corresponding thereto may be a red color filter that selectively transmits red light. When the second intermediate layer 2202 emits blue light, the second color filter 622 corresponding thereto may be a blue color filter that selectively transmits blue light. When the third intermediate layer 2203 emits green light, the third color filter 623 corresponding thereto may be a green color filter that selectively transmits green light.

The overcoat layer 630 may be positioned to cover the light-shielding layer 610 and the color filter layer 620. The overcoat layer 630, which is a light-transmitting layer, may cover irregularities caused by the light-shielding layer 610 and the color filter layer 620, and may provide a flat upper surface. The overcoat layer 630 may include a colorless light-transmitting organic material such as an acrylic resin.

The window layer WU may be disposed on the color filter layer CU. The optically clear adhesion member OCA may be disposed between the color filter layer CU and the window layer WU.

Although not shown in FIG. 8K, the display apparatus 1 may further include a low reflection layer (not shown) positioned on the second metal bank layer 323. The low reflection layer may be a layer having a lower surface reflectance than the second metal bank layer 323. For example, the low reflection layer may include at least one of copper oxide (CuO), calcium oxide (CaO), molybdenum oxide (MoOₓ), and zinc oxide (ZnO). According to some embodiments, the low reflection layer may include a mixture of copper oxide (CuO) and calcium oxide (CaO).

According to embodiments, light emitted by the first light-emitting diode ED1, the second light-emitting diode ED2, and the third light-emitting diode ED3 and incident upon an interface between the inorganic encapsulation layer 510 and the planarization layer 520 in an oblique direction (e.g., second path L2) within the pixel opening OP may travel along a path substantially perpendicular to the upper surface of the substrate 100 (e.g., a third path L3), due to a difference between the refractive indexes of the inorganic encapsulation layer 510 and the planarization layer 520. Accordingly, the front light-emission efficiency of the display apparatus 1 may be improved without including a separate optical function layer.

According to an embodiment as described above, a display apparatus 1 providing improved light-emission efficiency, and a method of manufacturing (or providing) the same may be realized. Of course, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a light-emitting element comprising a pixel electrode, an intermediate layer and an opposite electrode;
a bank layer comprising:
an inorganic bank layer, a first metal bank layer and a second metal bank layer sequentially on the pixel electrode, and
the inorganic bank layer, the first metal bank layer, and the second metal bank layer together defining a pixel opening of the bank layer which corresponds to the pixel electrode;
an inorganic encapsulation layer on the pixel electrode and having a first refractive index; and
a planarization layer on the inorganic encapsulation layer and having a second refractive index which is greater than the first refractive index.

2. The display apparatus of claim 1, wherein
the first refractive index of the inorganic encapsulation layer is about 1.3 to about 1.6, and
the second refractive index of the planarization layer is about 1.6 to about 2.5.

3. The display apparatus of claim 1, wherein
the first metal bank layer and the second metal bank layer respectively comprise a lateral surface defining the pixel opening, and
the second metal bank layer protrudes further than the lateral surface of the first metal bank layer to define a tip of the second metal bank layer, the tip defining the lateral surface of the second metal bank layer.

4. The display apparatus of claim 3, wherein
the tip of the second metal bank layer comprises a lower surface, and
the inorganic encapsulation layer is in direct contact with the lower surface of the tip of the second metal bank layer.

5. The display apparatus of claim 1, wherein
the planarization layer is in the pixel opening of the bank layer, and
the planarization layer forms an interface with the inorganic encapsulation layer, the interface corresponding to the pixel opening.

6. The display apparatus of claim 1, further comprising an organic bank layer between the second metal bank layer and the inorganic encapsulation layer.

7. The display apparatus of claim 1, wherein
the first metal bank layer comprises a lateral surface defining the pixel opening, and
the opposite electrode is in direct contact with the lateral surface of the first metal bank layer which defines the pixel opening.

8. The display apparatus of claim 1, further comprising a protective layer on the planarization layer, the protective layer having a third refractive index which is less than the second refractive index of the planarization layer.

9. The display apparatus of claim 8, further comprising:
a light-shielding layer on the protective layer and defining a filter opening overlapping the pixel electrode; and
a color filter corresponding to the filter opening and the pixel electrode.

10. The display apparatus of claim 8, wherein at a position adjacent to the pixel opening, the inorganic encapsulation layer and the protective layer are in direct contact with each other.

11. A method of providing a display apparatus, the method comprising:
providing a pixel electrode of a light-emitting element, and an electrode protection layer which is on the pixel electrode;
providing, on the electrode protection layer, a bank layer comprising an inorganic bank layer, a first metal bank layer and a second metal bank layer in order from the electrode protection layer;
providing an organic bank layer which is on the bank layer and defines an opening which overlaps the pixel electrode;
providing a pixel opening which is in the bank layer, corresponds to the pixel electrode and exposes the electrode protection layer to outside the bank layer, by using the organic bank layer as a mask;
providing an intermediate layer of the light-emitting element on the pixel electrode, through the pixel opening of the bank layer;
providing, on the pixel electrode, an opposite electrode of the light-emitting element, through the pixel opening of the bank layer;
providing an inorganic encapsulation layer covering the opposite electrode and having a first refractive index; and
providing a planarization layer on the inorganic encapsulation layer and having a second refractive index which is greater than the first refractive index of the inorganic encapsulation layer.

12. The method of claim 11, wherein
the providing of the pixel opening comprises etching the first metal bank layer and the second metal bank layer of the bank layer, and
the etching of the bank layer defines:
the first metal bank layer and the second metal bank layer respectively comprising a lateral surface defining the pixel opening, and
the second metal bank layer protruding further than the lateral surface of the first metal bank layer to define a tip of the second metal bank layer, the tip defining the lateral surface of the second metal bank layer.

13. The method of claim 12, wherein
the tip of the second metal bank layer comprises a lower surface, and
the providing of the inorganic encapsulation layer comprises directly contacting the inorganic encapsulation layer with the lower surface of the tip of the second metal bank layer.

14. The method of claim 11, wherein
the planarization layer is in the pixel opening of the bank layer, and
the planarization layer forms an interface with the inorganic encapsulation layer, the interface corresponding to the pixel opening.

15. The method of claim 11, further comprising providing a protective layer which is on the planarization layer and has a third refractive index less than the second refractive index of the planarization layer.

16. The method of claim 15, further comprising, between the providing of the pixel opening of the bank layer and the providing of the intermediate layer of the light-emitting element, removing the organic bank layer.

17. The method of claim 15, further comprising:
providing a light-shielding layer which is on the protective layer and defines a filter opening overlapping the pixel electrode; and
providing a color filter corresponding to the filter opening and the pixel electrode.

18. The method of claim 15, wherein
the providing of the intermediate layer of the light-emitting element comprises providing an intermediate layer material both on the pixel electrode and on the bank layer, and
the intermediate layer material which is on the pixel electrode is separated from the intermediate layer material which is on the bank layer.

19. The method of claim 11, wherein
a lateral surface of the first metal bank layer defines the pixel opening, and
the providing of the opposite electrode directly contacts the opposite electrode with the lateral surface of the first metal bank layer.

20. The method of claim 11, wherein the providing of the pixel opening in the bank layer comprises removing a first portion of the electrode protective layer and maintaining a second portion of the electrode protective layer which is at an edge of the pixel electrode.
